(19) United States
(12) Patent Application Publication
(10) Pub. No.: US 2015/0372165 A1
(43) Pub. Date: Dec. 24, 2015

(54) PHOTOELECTRIC CONVERTING ELEMENT

(71) Applicant: Sharp Kabushiki Kaisha, Osaka-shi, Osaka (JP)

(72) Inventors: Masatomi HARADA, Osaka-shi (JP); Takeshi KAMIKAWA, Osaka-shi (JP); Kazuya TSUJINO, Osaka-shi (JP)

(21) Appl. No.: 14/767,924

(22) PCT Filed: Apr. 9, 2014
(86) PCT No.: PCT/JP2014/060241

§ 371 Date: Aug. 14, 2015

(30) Foreign Application Priority Data
Apr. 25, 2013 (JP) 2013-092078

(51) Int. Cl. H01L 31/0236; H01L 31/068; H01L 31/0376

(52) U.S. Cl. CPC H01L 31/02363; H01L 31/03762; H01L 31/068

(57) ABSTRACT

There is provided a photoelectric converting element in which conversion efficiency increases, by being evenly passivated. The photoelectric converting element is a photoelectric converting element that converts light to electricity, and has a silicon substrate (101) having a textured structure containing plural inclined planes (101a) formed at least on one surface. In a section perpendicular to a line at which two adjacent inclined planes (101a) intersect each other having a concave portion (TXb) of the textured structure interposed therebetween, when a distance between a point Pa at which a tangential line on one of the two inclined planes (101a) and a tangential line of the deepest portion of the concave portion intersect each other and a point Pb at which a tangential line of the other one of the two inclined planes (101a) and a tangential line of the deepest portion of the concave portion intersect each other is a bottom width Lb, the bottom width Lb is 20 nm or greater.

### TECHNICAL FIELD

The invention relates to a photoelectric converting element that converts light to electricity.

### BACKGROUND ART

In the related art, an optical confinement structure in which a pyramidal textured structure is formed based on a (111) surface by anisotropically etching a (100) surface of a monocrystalline silicon substrate is known. According to this optical confinement structure, the reflectivity on a surface of a silicon substrate is reduced, and thus a short circuit current can be increased.

In Japanese Unexamined Patent Application Publication No. 2011-77240, a photovoltaic device including a first conductive monocrystalline silicon substrate, another conductive amorphous silicon layer which is formed on the monocrystalline silicon substrate surface via an intrinsic amorphous silicon layer, and a transparent conductive film which is formed on the amorphous silicon layer is disclosed. In the photovoltaic device, a surface on which an amorphous silicon layer of the monocrystalline silicon substrate is provided is regulated such that a standard deviation of unevenness of the surface from an approximation straight line is less than 1.0 nm.

### SUMMARY OF INVENTION

In a crystal silicon-based photoelectric converting element, a minority carrier lifetime on the surface decreases due to dangling bonds. Therefore, a passivation film is formed on the surface of the silicon substrate, and minority carriers on the surface are suppressed from decreasing.

Meanwhile, if a passivation film is formed on the textured structure described above, strong stress is applied to the passivation film near the concave portion, such that the effect of the passivation decreases.

An object of the invention is to provide a photoelectric converting element in which conversion efficiency is enhanced by evenly passivating a light receiving surface having a pyramidal textured structure.

The photoelectric converting element described herein is a photoelectric converting element that converts light to electricity, and includes a silicon substrate having a textured structure including plural inclined planes which is formed at least on one surface. In a section perpendicular to a line at which two adjacent inclined planes with a concave portion of the textured structure interposed therebetween intersect each other, a distance between a point at which a tangential line of one of the two inclined planes and a tangential line of the deepest portion of the concave portion intersect each other and a point at which a tangential line of the other one of the two inclined planes and a tangential line of the deepest portion of the concave portion intersect each other is a bottom width, the bottom width is in a range of 20 nm or greater.

According to this configuration, if the bottom width is 20 nm or greater, stress applied from the two adjacent inclined planes with a concave portion interposed therebetween can be relieved. Therefore, if an even passivation film is formed on a light receiving surface having a pyramidal textured structure, conversion efficiency of the photoelectric converting element can be enhanced.

### BRIEF DESCRIPTION OF DRAWINGS

FIG. 1 is a sectional view schematically illustrating a configuration of a photoelectric converting element according to a first embodiment of the invention.

FIG. 2 is a plan view schematically illustrating a textured structure of a silicon substrate.

FIG. 3 is a sectional view taken along a line III-III of FIG. 2, and is a TEM image of a section near a concave portion.

FIG. 4 is a diagram schematically illustrating a bottom width Lb.

FIG. 5 is a diagram schematically illustrating the bottom width Lb and is a diagram illustrating a case where the concave portion has no flat portion.

FIG. 6A is a diagram illustrating an example of a method of manufacturing a photoelectric converting element according to the first embodiment of the invention.

FIG. 6B is a diagram illustrating an example of the method of manufacturing the photoelectric converting element according to the first embodiment of the invention.

FIG. 6C is a diagram illustrating an example of a method of manufacturing the photoelectric converting element according to the first embodiment of the invention.

FIG. 6D is a diagram illustrating an example of a method of manufacturing the photoelectric converting element according to the first embodiment of the invention.

FIG. 7 is a TEM image of a section near a concave portion in a case where the bottom width Lb is less than 20 nm.

FIG. 8 is an enlarged view of an area A in FIG. 7.

FIG. 9 is a sectional view schematically illustrating a configuration of a photoelectric converting element according to a second embodiment of the invention.

FIG. 10 is a sectional view schematically illustrating a configuration of a photoelectric converting element according to a third embodiment of the invention.

FIG. 11A is a diagram illustrating a method of manufacturing the photoelectric converting element according to the third embodiment of the invention.

FIG. 11B is a diagram illustrating the method of manufacturing the photoelectric converting element according to the third embodiment of the invention.

FIG. 11C is a diagram illustrating the method of manufacturing the photoelectric converting element according to the third embodiment of the invention.

FIG. 12 is a sectional view schematically illustrating a configuration of a photoelectric converting element according to a fourth embodiment of the invention.

FIG. 13 is a sectional view schematically illustrating a configuration of a photoelectric converting element according to a fifth embodiment of the invention.

FIG. 14 is a sectional view schematically illustrating a configuration of a photoelectric converting element according to a sixth embodiment of the invention.

FIG. 15 is a plan view illustrating the photoelectric converting element according to the sixth embodiment of the invention seen from a back surface side.

FIG. 16A is a diagram illustrating an example of a method of manufacturing of the photoelectric converting element according to the sixth embodiment of the invention.

FIG. 16B is a diagram illustrating an example of the method of manufacturing of the photoelectric converting element according to the sixth embodiment of the invention.

FIG. 16C is a diagram illustrating an example of the method of manufacturing of the photoelectric converting element according to the sixth embodiment of the invention.

FIG. 16D is a diagram illustrating an example of the method of manufacturing of the photoelectric converting element according to the sixth embodiment of the invention.

FIG. 16E is a diagram illustrating an example of the method of manufacturing of the photoelectric converting element according to the sixth embodiment of the invention.

FIG. 16F is a diagram illustrating an example of the method of manufacturing of the photoelectric converting element according to the sixth embodiment of the invention.

FIG. 17 is a sectional view schematically illustrating a configuration of a photoelectric converting element according to the seventh embodiment of the invention.

FIG. 18 is a TEM image of a section near a concave portion of a textured structure of a photoelectric converting element according to Example 1.

FIG. 19 is a TEM image of a section near a concave portion of a textured structure of a photoelectric converting element according to Comparative Example 1.

FIG. 20 is a graph illustrating a relationship between reflectivity and a bottom width Lb.

FIG. 21 is a graph illustrating a relationship between short-circuit current density Jsc and a bottom width Lb.

FIG. 22 is a graph illustrating a relationship between a carrier lifetime and the bottom width Lb.

FIG. 23 is a graph illustrating a relationship between an open circuit voltage Voc and the bottom width Lb.

FIG. 24 is a graph illustrating a relationship between series resistance Rs and the bottom width Lb.

FIG. 25 is a graph illustrating a relationship between conversion efficiency η and the bottom width Lb.

FIG. 26 is a diagram illustrating a portion of FIG. 25 in an enlarged manner.

FIG. 27 is a graph illustrating a relationship between an inclination angle α and the bottom width Lb.

FIG. 28 is a diagram schematically illustrating an example of a configuration of a photoelectric converting module according to the embodiment.

FIG. 29 is a diagram schematically illustrating an example of a configuration of a photovoltaic power generation system according to the embodiment.

FIG. 30 is a diagram schematically illustrating an example of a configuration of a photoelectric converting module array illustrated in FIG. 29.

FIG. 31 is a diagram schematically illustrating another example of a configuration of a photovoltaic power generation system according to the embodiment.

FIG. 32 is a diagram schematically illustrating another example of the configuration of the photovoltaic power generation system according to the embodiment.

FIG. 33 is a diagram schematically illustrating another example of the configuration of the photovoltaic power generation system according to the embodiment.

### DESCRIPTION OF EMBODIMENTS

Hereinafter, with reference to the drawings, embodiments of the invention are described in detail. In the drawings, identical or similar portions are denoted by the same reference numerals, and the descriptions thereof are not repeated. In addition, for easier understanding, in the drawings referenced below, configurations thereof are simplified or schematically illustrated, or a portion of configuration members is omitted. In addition, dimension ratios between configuration members illustrated in the respective drawings do not indicate the actual dimension ratios.

### First Embodiment

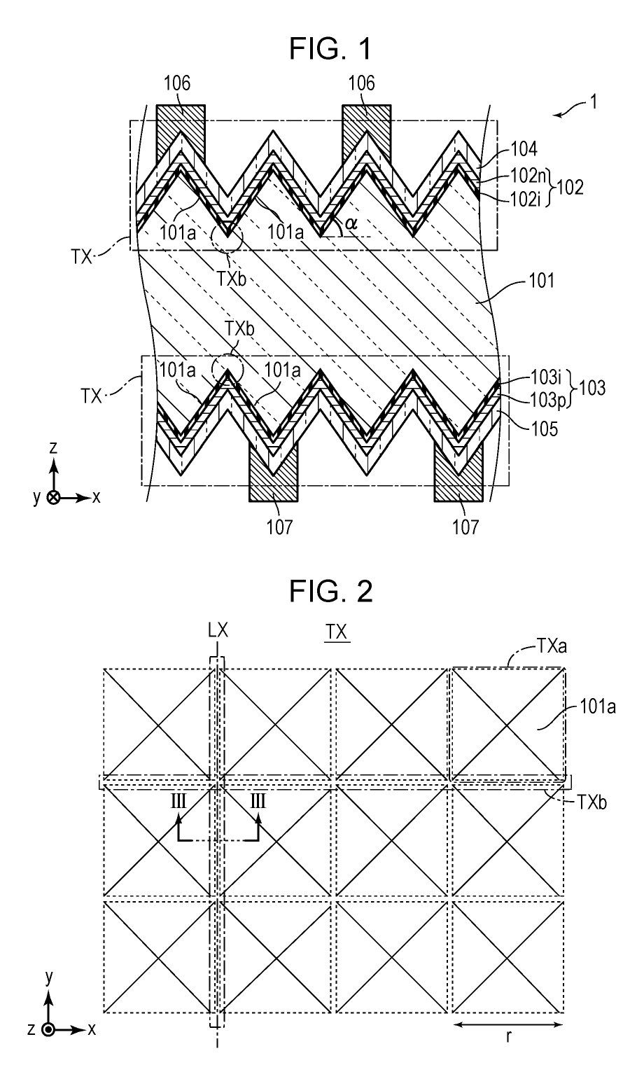

FIG. 1 is a sectional view schematically illustrating a configuration of a photoelectric converting element 1 according to a first embodiment of the invention. The photoelectric converting element 1 includes a silicon substrate 101, semiconductor layers 102 and 103, transparent conductive films 104 and 105, and electrodes 106 and 107. Hereinafter, the thickness direction of the electrodes 106 and 107 is referred to as a z direction, and a plane (xy plane) which is perpendicular to the z direction is referred to as a reference plane.

The silicon substrate 101 is a monocrystalline substrate, the conductivity type of which is the n type. The thickness of the silicon substrate 101 is, for example, in the range of 80 μm to 200 μm. The resistivity of the silicon substrate 101 is, for example, in the range of 1 Ωcm to 4 Ωcm.

Textured structures TX including plural inclined planes 101a are formed on both surfaces of the silicon substrate 101. The textured structures TX reduce the surface reflectivity of the silicon substrate 101. The photoelectric converting element 1 can obtain more light due to the textured structures TX.

The semiconductor layer 102, the transparent conductive film 104, and electrodes 106 are formed in this sequence, on the surface (hereinafter, referred to as a light receiving surface) on which light of the silicon substrate 101 is incident. A semiconductor layer 103, the transparent conductive film 105, and electrodes 107 are formed in this sequence, on the other surface (hereinafter, referred to as back surface) of the silicon substrate 101.

The semiconductor layer 102 includes an i-type amorphous film 102i and an n-type amorphous film 102n. The i-type amorphous film 102i and the n-type amorphous film 102n are formed in this sequence, in such a manner as to cover the light receiving surface of the silicon substrate 101. In the same manner, the semiconductor layer 103 includes an i-type amorphous film 103i and a p-type amorphous film 103p. The i-type amorphous film 103i and the p-type amorphous film 103p are formed in this sequence, in a manner of covering the back surface of the silicon substrate 101.

The i-type amorphous films 102i and 103i are amorphous semiconductor films which are substantially intrinsic and contain hydrogen. In addition, in this specification, a microcrystalline semiconductor is included in the amorphous semiconductor. The microcrystalline semiconductor is a semiconductor of which an average particle diameter of a semiconductor crystal deposited in the amorphous semiconductor is in the range of 1 nm to 50 nm.

The i-type amorphous films 102i and 103i are films of, for example, i-type amorphous silicon, i-type amorphous silicon germanium, i-type amorphous germanium, i-type amorphous silicon carbide, i-type amorphous silicon nitride, i-type amorphous silicon oxide, and i-type amorphous silicon carbon oxide. The thicknesses of the i-type amorphous films 102i and 103i are, for example, in the range of several angstroms to 25 nm.

The n-type amorphous film 102n is an amorphous semiconductor film, the conductivity type of which is the n type, and which contains hydrogen. The n-type amorphous film 102n contains, for example, phosphorus, as a dopant. The concentration of the dopant is, for example, in the range of 1×10¹⁸ cm⁻³ to 1×10²¹ cm⁻³. The n-type amorphous film 102n is a film composed of, for example, n-type amorphous silicon, n-type amorphous silicon germanium, n-type amorphous germanium, n-type amorphous silicon carbide, n-type amorphous silicon nitride, n-type amorphous silicon oxide, and n-type amorphous silicon carbon oxide. The thickness of the n-type amorphous film 102n is, for example, in the range of 2 nm to 50 nm.

The p-type amorphous film 103p is an amorphous semiconductor film, the conductivity type of which is the p type, and which contains hydrogen. The p-type amorphous film 103p contains, for example, boron, as a dopant. The concentration of the dopant is, for example, 1×10¹⁸ cm⁻³ to 1×10²¹ cm⁻³. The p-type amorphous film 103p is a film composed of, for example, p-type amorphous silicon, p-type amorphous silicon germanium, p-type amorphous germanium, p-type amorphous silicon carbide, p-type amorphous silicon nitride, p-type amorphous silicon oxide, and p-type amorphous silicon carbon oxide. The thickness of the p-type amorphous film 103p is, for example, in the range of 2 nm to 50 nm.

The i-type amorphous films 102i and 103i function as passivation films of the silicon substrate 101, as described below. Accordingly, the photoelectric converting element 1 preferably includes the i-type amorphous films 102i and 103i. However, the photoelectric converting element 1 may not include the i-type amorphous films 102i and 103i.

The semiconductor layer 102 is a combination of i-type amorphous silicon and n-type amorphous silicon. In addition, the semiconductor layer 103 is preferably a combination of i-type amorphous silicon and p-type amorphous silicon.

The transparent conductive film 104 is formed to cover the semiconductor layer 102. The transparent conductive film 105 is formed to cover the semiconductor layer 103. The transparent conductive films 104 and 105 are, for example, transparent conductive oxide (TCO). The thicknesses of the transparent conductive films 104 and 105 are, for example, in the range of 50 nm to 100 nm.

In addition, as the transparent conductive films 104 and 105, indium tin oxide (ITO), SnO₂, or ZnO are preferably used.

The electrodes 106 are formed on the transparent conductive film 104, and the electrodes 107 are formed on the transparent conductive film 105. The electrodes 106 and 107 are, for example, resin compositions obtained by kneading a conductive filler such as silver powder.

FIG. 2 is a plan view schematically illustrating the textured structures TX of the silicon substrate 101.

The textured structures TX contain plural convex portions TXa. In the example illustrated in FIG. 2, each of the convex portions TXa has a pyramidal shape configured with the four inclined planes 101a. As described below, the textured structures TX can be formed by anisotropically etching a (100) surface of a monocrystalline silicon substrate. According to this, the inclined planes 101a which are based on by a (111) surface and are symmetrical to each other are formed.

In addition, the textured structures TX in FIG. 2 are provided as examples. The inclined planes 101a may have an asymmetrical shape, or the convex portions TXa may include three or less or five or more inclined planes.

With respect to the size of the convex portions TXa, a length (length of the longest side, if lengths of the sides on the bottom surface are different from each other) r of one side on the bottom surface of the convex portions TXa is preferably 0.6 μm to 20 μm, because the effect of scattering light in a wavelength of 350 nm to 1,100 nm which is included in the sunlight can be increased.

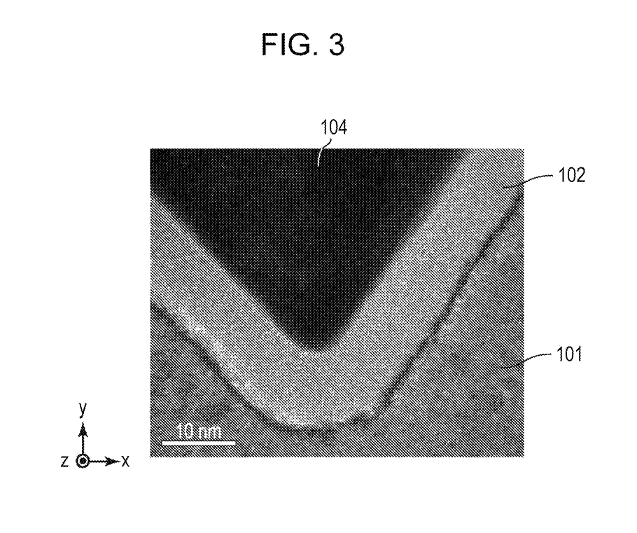

A concave portion TXb is formed between the neighboring convex portions TXa. FIG. 3 is a sectional view taken along a line III-III of FIG. 2, and is an image of a transmission electron microscope (TEM) of a section near the concave portion TXb.

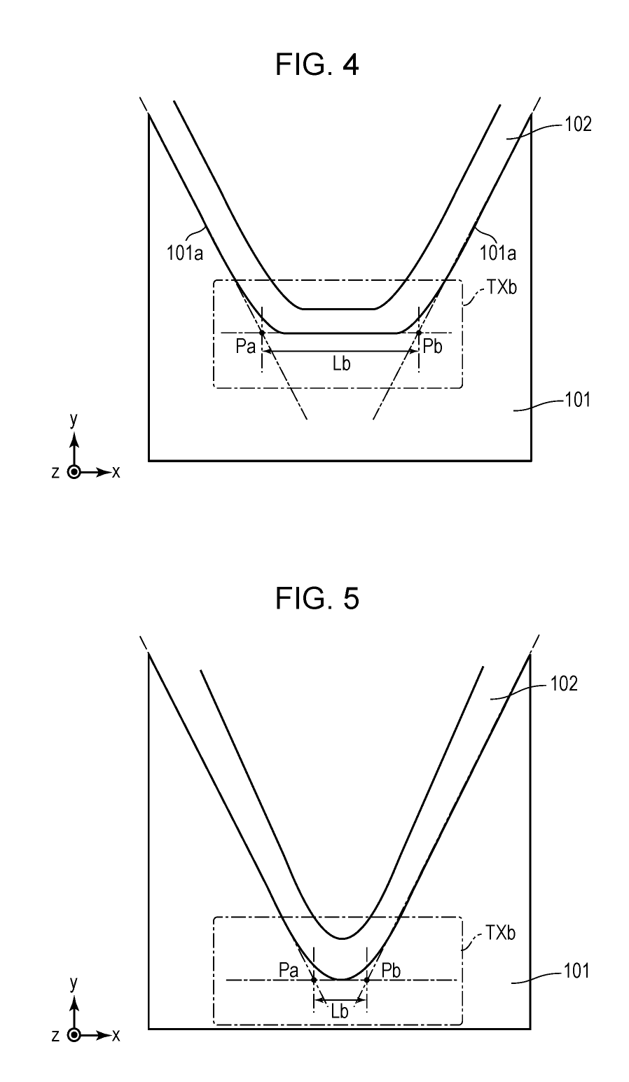

FIG. 4 is a diagram schematically illustrating the bottom width Lb. In the same manner as in FIG. 3, FIG. 4 illustrates a section along the line III-III of FIG. 2. More specifically, FIG. 4 illustrates a section perpendicular to the line LX (FIG. 2) at which the two adjacent inclined planes 101a with the concave portion TXb interposed therebetween intersect each other. In the section, a point at which a tangential line of one of the two inclined planes 101a and a tangential line of the deepest portion of the concave portion TXb intersect each other is a point Pa, and a tangential line of the other one of the two inclined planes 101a and a tangential line of the deepest portion of the concave portion TXb intersect each other is a point Pb. Also, the length between the point Pa and the point Pb is referred to as a bottom width Lb.

That is, on a section perpendicular to a line LX (FIG. 2) at which the two adjacent inclined planes 101a with the concave portion TXb interposed therebetween intersect each other, a distance between the point Pa at which a tangential line of one of the two inclined planes 101a and a tangential line of the deepest portion of the concave portion TXb intersect each other and the point Pb at which a tangential line of the other one of the two inclined planes 101a and a tangential line of the deepest portion of the concave portion TXb intersect to each other is referred to as the bottom width Lb.

FIG. 5 is a diagram schematically illustrating the bottom width Lb in a case where the concave portion TXb has no flat portion (a portion parallel to a reference plane). As illustrated in FIG. 5, according to the definition described above, even if the concave portion TXb has no flat portion, the bottom width Lb can be uniquely determined.

The photoelectric converting element 1 according to the embodiment has a bottom width Lb of 20 nm or greater.

### [Method of Manufacturing the Photoelectric Converting Element 1]

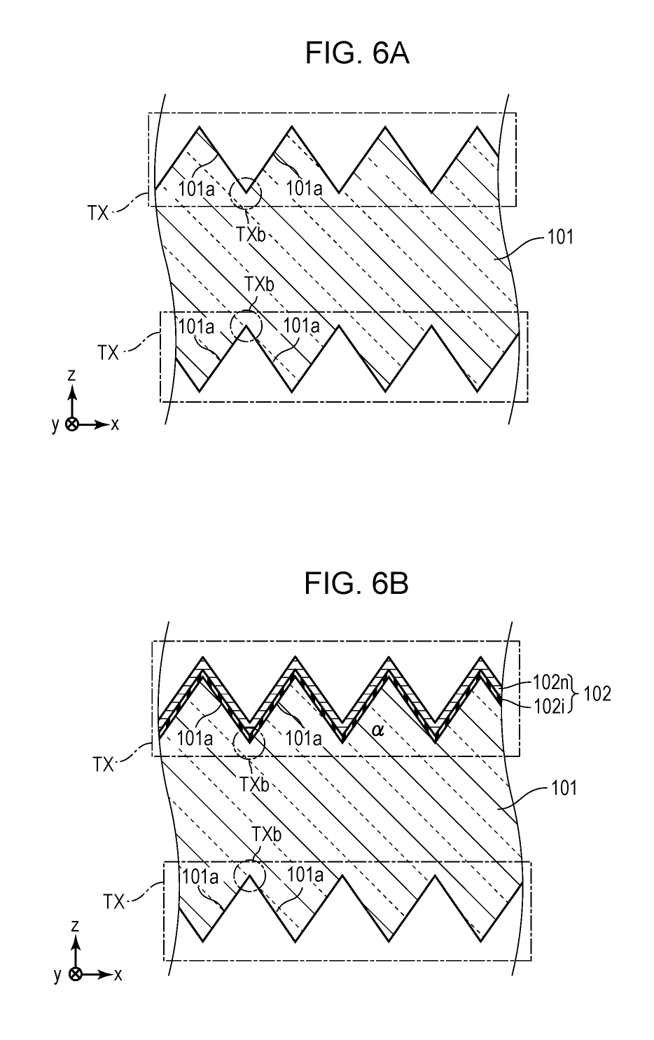

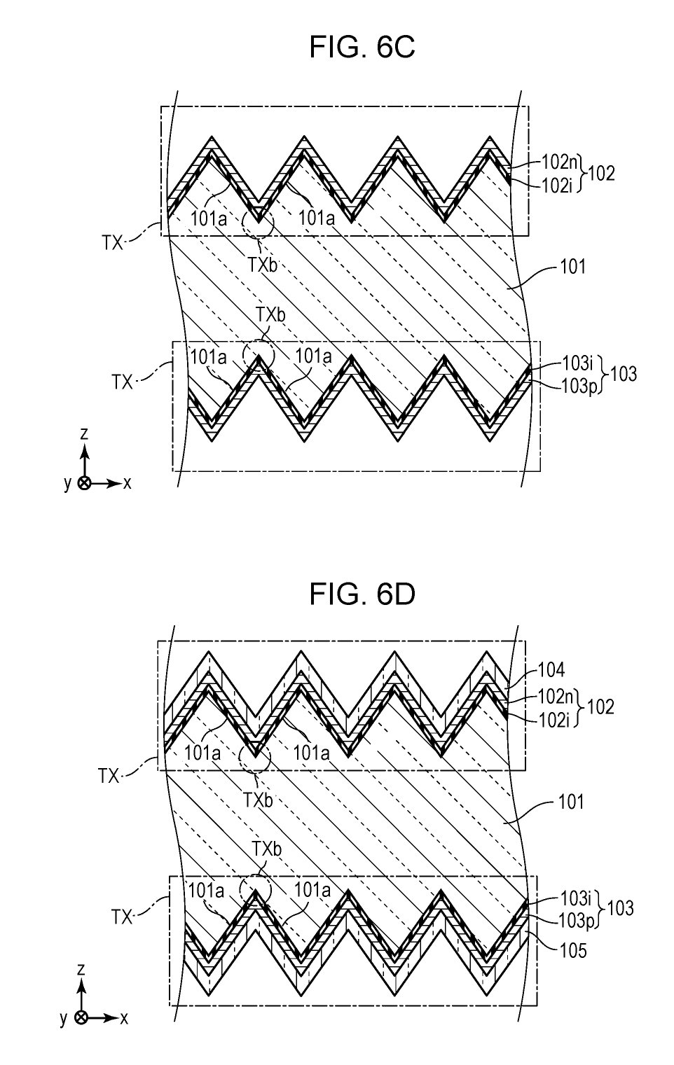

Subsequently, with reference to FIGS. 6A to 6D, an example of a method of manufacturing the photoelectric converting element 1 is described. However, the method of manufacturing the photoelectric converting element 1 is not limited to the method described below.

The silicon substrate 101 having the textured structures TX formed on the both surfaces is manufactured (FIG. 6A). First, a monocrystalline silicon substrate, a flat surface of which is a (100) surface, is immersed in an alkaline solution. As the solution, for example, a mixed solution of KOH in the range of 1% by weight to 5% by weight and isopropyl alcohol in the range of 1% by weight to 10% by weight can be used. The processing temperature can be, for example, 80° C. to 90° C., and the processing time is, for example, 30 minutes.

According to this method, owing to the difference between a (100) surface etching speed and a (111) surface etching speed, the inclined planes 101a which are based on the (111) surface and are symmetrical to each other are formed. Here, an angle formed by the inclined planes 101a and the reference plane is defined as the inclination angle α (FIG. 1). In addition, the angle between the (111) surface and the reference plane is about 54.7°.

Subsequently, the silicon substrate 101 having the textured structures TX formed on both surfaces is immersed in an aqueous mixed solution (hereinafter, referred to as “nitro hydrofluoric acid”) of hydrofluoric acid and nitric acid and is further etched. As the nitro hydrofluoric acid, for example, an aqueous solution obtained by mixing 50% by weight of a hydrofluoric acid aqueous solution and 60% by weight of a nitric acid aqueous solution in a mixture ratio of 1:10 to 1:100 may be used. The aqueous solution may be purely diluted to be used. The processing time is, for example, 30 seconds to 300 seconds.

By performing the etching, the surface of the silicon substrate approaches the flat surface. That is, by performing the etching, the height of the convex portions TXa becomes small, the bottom width Lb becomes large, and the inclination angle α becomes small.

As described below, if the bottom width Lb becomes large, the passivation functions of the i-type amorphous films 102i and 103i increase. If the bottom width Lb is 20 nm or greater, the passivation function can be prominently increased. The bottom width Lb is preferably 100 nm or greater.

As the surface of the silicon substrate approaches the flat surface, the optical confinement effect of the textured structures TX is closed and the effect decreases. Therefore, the bottom width Lb is preferably 600 nm or less. In addition, the inclination angle α is preferably 48° or greater.

Subsequently, the semiconductor layer 102 is formed on the light receiving surface side of the silicon substrate 101 (FIG. 6B).

First, the i-type amorphous film 102i is formed on the light receiving surface of the silicon substrate 101, for example, by plasma chemical vapour deposition (plasma CVD). For example, an i-type amorphous silicon film can be formed by performing plasma CVD under the conditions of a substrate temperature: 130° C. to 220° C., a H₂ gas flow rate: 200 sccm to 3,000 sccm, a SiH₄ gas flow rate: 200 sccm to 1,000 sccm, pressure: 30 Pa to 500 Pa, and density of high-frequency electric power: 5 mW/cm² to 40 mW/cm².

Subsequently, the n-type amorphous film 102n is formed on the i-type amorphous film 102i by the plasma CVD. An n-type amorphous silicon film on which phosphorus (P) is doped can be formed by performing the plasma CVD, for example, under the conditions of a substrate temperature: 130° C. to 220° C., a H₂ gas flow rate: 200 sccm to 3,000 sccm, a SiH₄ gas flow rate: 200 sccm to 1,000 sccm, a PH₃/H₂ gas flow rate: 30 sccm to 500 sccm, a pressure: 20 Pa to 100 Pa, and a high-frequency electric power density: 5 mW/cm² to 40 mW/cm². In addition, the PH₃/H₂ gas refers to gas obtained by diluting PH₃ gas with H₂ gas, and the concentration of PH₃ to H₂ can be, for example, 1%.

Subsequently, the semiconductor layer 103 is formed on the back surface of the silicon substrate 101 (FIG. 6C).

First, the i-type amorphous film 103i is formed on the back surface of the silicon substrate 101, for example, by the plasma CVD. The conditions for forming the i-type amorphous film 103i are the same as those for the i-type amorphous film 102i. The i-type amorphous film 102i and the i-type amorphous film 103i may be formed under the same conditions, or may be formed under different conditions.

Subsequently, the p-type amorphous film 103p is formed on the i-type amorphous film 103i, for example, by the plasma CVD. A p-type amorphous silicon film on which boron (B) is doped can be formed by performing the plasma CVD, for example, under the conditions of a substrate temperature: 130° C. to 220° C., a H₂ gas flow rate: 200 sccm to 3,000 sccm, a SiH₄ gas flow rate: 200 sccm to 1,000 sccm, a B₂H₆/H₂ gas flow rate: 30 sccm to 500 sccm, a pressure: 20 Pa to 100 Pa, and a high-frequency electric power density: 5 mW/cm² to 40 mW/cm². In addition, the B₂H₆/H₂ gas refers to gas obtained by diluting B₂H₆ gas with H₂ gas, and the concentration of B₂H₆ to H₂ can be, for example, 2%.

Subsequently, the transparent conductive film 104 is formed on the semiconductor layer 102, and the transparent conductive film 105 is formed on the semiconductor layer 103 (FIG. 6D).

As the transparent conductive films 104 and 105, for example, ITO can be formed by sputtering as described below. First, a sintered body of In₂O₃ powder in which 5% by weight of SnO₂ powder is mixed is provided on a cathode as a target. The silicon substrate 101 on which the semiconductor layers 102 and 103 are formed is disposed so as to be parallel to the cathode and the inside of the chamber is evacuated. Heating is performed such that the temperature of the silicon substrate 101 becomes 180° C., the mixed gas of Ar gas (flow rate: 200 sccm to 800 sccm) and O₂ gas (flow rate: 0 sccm to 30 sccm) is made to flow such that the pressure in the chamber is maintained at 0.4 Pa to 1.3 Pa, and a DC power of 0.2 kW to 2 kW is input to the cathode.

Finally, the electrodes 106 are formed on the transparent conductive film 104, and the electrodes 107 are formed on the transparent conductive film 105. The electrodes 106 and 107 can be formed, for example, by patterning Ag paste obtained by kneading silver (Ag) fine particles with an epoxy resin by screen printing and burning and hardening the Ag paste at 200° C., for 80 minutes.

In the above, an example of the method of manufacturing the photoelectric converting element 1 is described. In the example described above, the method of forming the textured structures TX by immersing the monocrystalline silicon substrate, the flat surface of which is the (100) surface, in the alkaline solution is described. However, the method of forming the textured structures TX is not limited to this. For example, the textured structures TX may be formed by dry etching using reactive gas.

[Effect of the Photoelectric Converting Element 1]

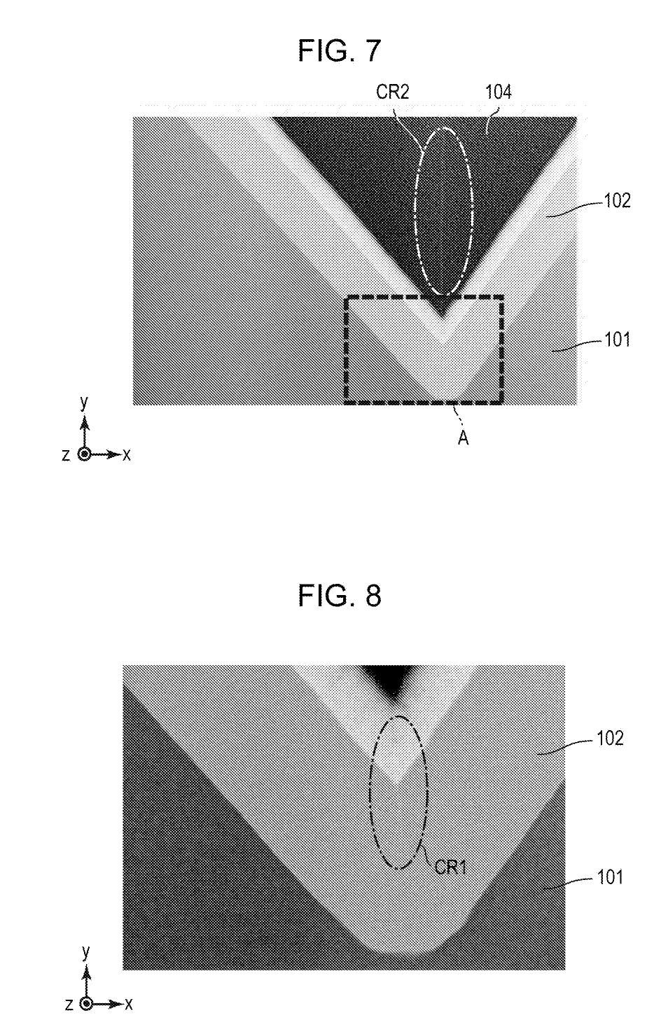

FIG. 7 is a TEM image of a section near a concave portion LXb in a case where the bottom width Lb is less than 20 nm. FIG. 8 is an enlarged view of an area A in FIG. 7.

As illustrated in FIG. 8, in a photoelectric converting element of which the bottom width Lb is less than 20 nm, a crack CR1 is generated on the semiconductor layer 102. It is considered that this is because strong stress is received from the inclined planes 101a on both sides when the semiconductor layer 102 is formed. The semiconductor layer 102 functions as a passivation film. However, the semiconductor layer 102 may not function as a passivation film in a portion in which the crack CR1 is generated. In addition, the semiconductor layer 102 functions as a carrier transport layer at the time of current extraction, but in a portion in which the crack CR1 is generated, carrier recombination occurs and the extracted current decreases.

As illustrated in FIG. 7, a crack CR2 is generated in the transparent conductive film 104. It is considered that this also is caused by the stress from the inclined planes 101a on both sides as described above. The transparent conductive film 104 functions as a carrier transport layer at the time of current extraction, but in a portion in which the crack CR2 is generated, carrier recombination occurs and the extracted current decreases. Further, since the transparent conductive film 104 is divided by the crack CR2, conductivity in the transverse direction deteriorates and, as a result, a series resistance Rs of the photoelectric converting element 1 becomes great.

On the back surface side of the photoelectric converting element 1, the same cracks may be generated in the semiconductor layer 103 and the transparent conductive film 105.

According to the embodiment, the bottom width Lb is 20 nm or greater. Accordingly, the stress from the inclined planes 101a can be relieved. Accordingly, the passivation functions of the semiconductor layers 102 and 103 are enhanced. Accordingly, the conversion efficiency of the photoelectric converting element 1 is enhanced. The relationship between the size of the bottom width Lb and the conversion efficiency of the photoelectric converting element 1 or the like is specifically described in the examples.

If the bottom width Lb is 20 nm or greater, the stress applied to the transparent conductive films 104 and 105 can be relieved. Accordingly, the series resistance Rs of the photoelectric converting element 1 can be decreased.

Accordingly, the i-type amorphous film 102i is formed on the light receiving surface side of the photoelectric converting element 1, and the i-type amorphous film 103i is formed on the back surface side. According to the embodiment, both surfaces of the photoelectric converting element 1 are passivated, and thus a higher passivation effect can be obtained. In addition, according to the embodiment, the photoelectric converting element 1 has a configuration in which a light receiving surface side and a back surface side are symmetrical to each other, such that bending in the step of manufacturing the photoelectric converting element 1 can be prevented.

According to the embodiment, the semiconductor layers 102 and 103 are formed with amorphous films. Therefore, the photoelectric converting element 1 can be produced without going through a high temperature process such that carrier lifetime can be increased.

In the above, the configuration, the manufacturing method, and the effect of the photoelectric converting element 1 according to the first embodiment are described. According to the embodiment, a pn junction is formed by forming a p-type semiconductor layer on the silicon substrate 101, a conductivity type of which is the n type. However, the same effect can be obtained if an n-type semiconductor layer is formed on a p-type silicon substrate.

In the example described above, an example of using a monocrystalline silicon substrate as the silicon substrate 101 is described. However, as the silicon substrate 101, a polycrystalline silicon substrate may be used. If the polycrystalline silicon substrate is used, for example, a stripe-shaped textured structure is formed by dry etching using reactive gas, and a bottom width may be adjusted by etching with nitro hydrofluoric acid.

The photoelectric converting element 1 may include a conductive film which does not have transmittance, instead of the transparent conductive film 105 on the back surface side. The conductive film is a film composed of metal such as Ag, Cu, Sn, Pt, Au, Ti, and Pd, and an alloy including one or more types of the metal above.

### Second Embodiment

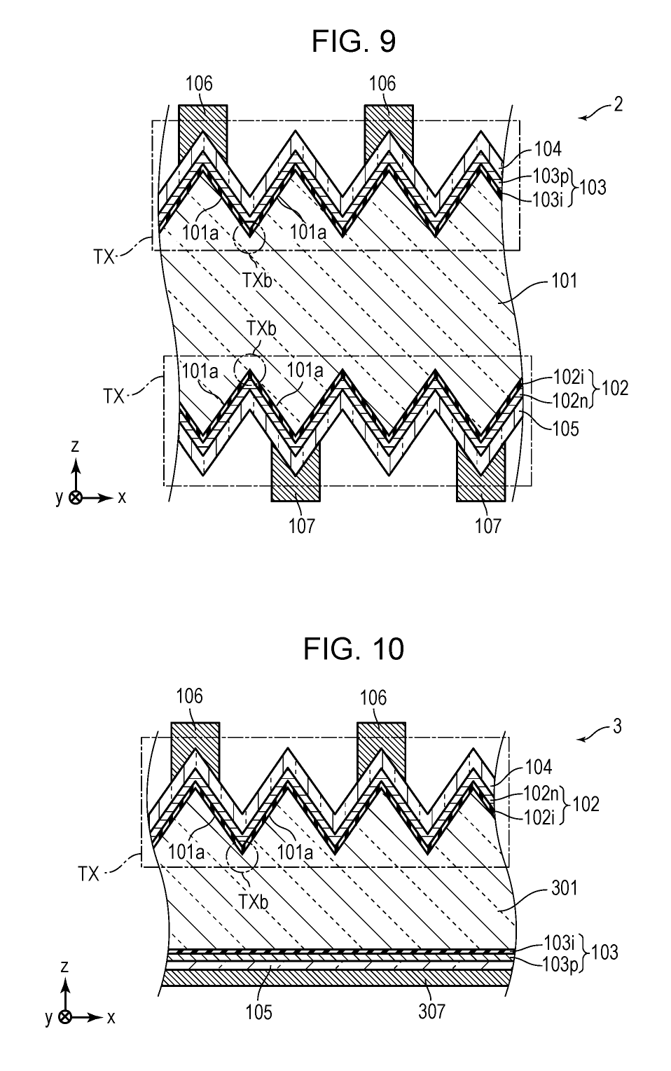

FIG. 9 is a sectional view schematically illustrating a configuration of a photoelectric converting element 2 according to the second embodiment of the invention. In the photoelectric converting element 2, the semiconductor layer 103 containing the p-type amorphous film 103p is formed on the light receiving surface side of the silicon substrate 101, and the semiconductor layer 102 containing the n-type amorphous film 102n is formed on the back surface side of the silicon substrate 101. The other configurations are the same as in the photoelectric converting element 1. Also in the photoelectric converting element 2, the textured structures TX are formed on the both surfaces of the silicon substrate 101, and the bottom width Lb is 20 nm or greater.

Also in this embodiment, the same effect as in the first embodiment can be obtained.

### Third Embodiment

FIG. 10 is a sectional view schematically illustrating a configuration of a photoelectric converting element 3 according to a third embodiment of the invention. Instead of the silicon substrate 101, the photoelectric converting element 3 includes a silicon substrate 301, a conductivity type of which is the n type, and in which the textured structures TX are formed only on the light receiving surface. Instead of the electrodes 107, the photoelectric converting element 3 includes an electrode 307 which is formed to cover substantially the entire conductive film 105. The other configuration is the same as in the photoelectric converting element 1. Also in the photoelectric converting element 3 and in the textured structure TX formed on the light receiving surface side, the bottom width Lb is 20 nm or greater.

### [Method of Manufacturing the Photoelectric Converting Element 3]

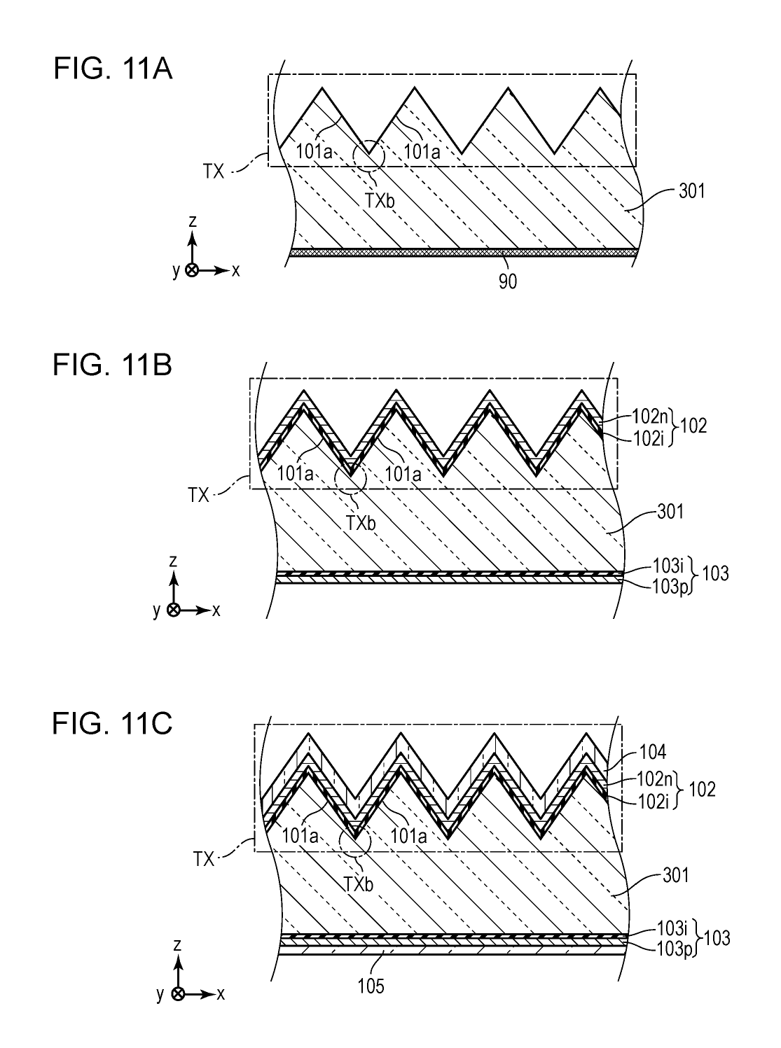

Hereinafter, with reference to FIGS. 11A to 11C, an example of a method of manufacturing the photoelectric converting element 3 is described. However, the method of manufacturing the photoelectric converting element 3 is not limited to the method described herein.

A silicon substrate 301 having the textured structure TX formed on one surface is produced (FIG. 11A). First, a film 90 of SiO₂ or the like is formed on one surface of the monocrystalline silicon substrate by sputtering or the like. Subsequently, using the film 90 as a mask, the silicon substrate is etched with the alkaline solution or the like, and the textured structure TX is formed on a surface opposite to the surface on which the film 90 is formed. After the textured structure TX is formed, the film 90 is removed.

Subsequently, the semiconductor layer 102 is formed on the light receiving surface side of the silicon substrate 301, and the semiconductor layer 103 is formed on the back surface side (FIG. 11B). A method of forming the semiconductor layers 102 and 103 is the same as that in the first embodiment.

Subsequently, the transparent conductive film 104 is formed on the semiconductor layer 102, and the transparent conductive film 105 is formed on the semiconductor layer 103 (FIG. 11C). The method of forming the transparent conductive films 104 and 105 is as that in the first embodiment.

Subsequently, the electrodes 106 are formed on the transparent conductive film 104, and a conductive film 307 is formed on the transparent conductive film 105. The method of forming the electrodes 106 are the same as that in the first embodiment. The electrode 307 can be formed, for example, by sputtering.

### [Effect of Third Embodiment]

Also in this embodiment, in the concave portion TXb of the textured structure TX formed on the light receiving surface side, the stress applied to the semiconductor layer 102 and the transparent conductive film 104 is relieved. Accordingly, the conversion efficiency can be improved.

According to the embodiment, the electrode 307 is formed so as to cover substantially the entire surface of the transparent conductive film 105. The light reaching the back surface from the light receiving surface of the photoelectric converting element 3 is reflected by the electrode 307. Accordingly, the photoelectric converting element 3 can obtain more light.

### Fourth Embodiment

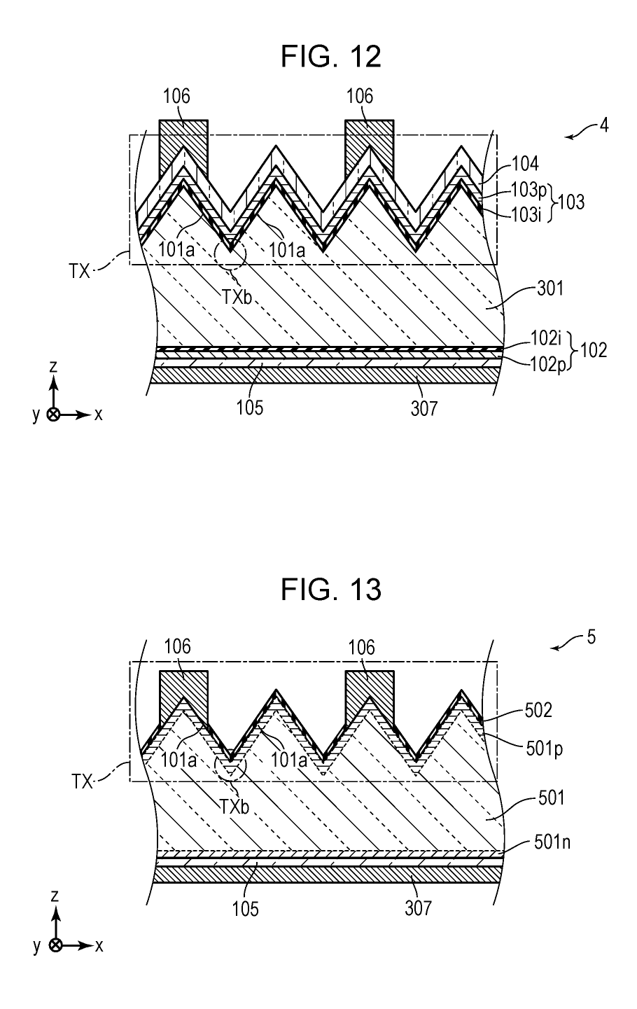

FIG. 12 is a sectional view schematically illustrating a configuration of a photoelectric converting element 4 according to the fourth embodiment of the invention. In the photoelectric converting element 4, the semiconductor layer 103 including the p-type amorphous film 103p is formed on the light receiving surface of the silicon substrate 301, the semiconductor layer 102 containing the n-type amorphous film 102n is formed on the back surface side of the silicon substrate 301. The other configuration is the same as that in the photoelectric converting element 3. Also in the photoelectric converting element 4, the textured structure TX is formed on the light receiving surface side of the silicon substrate 301, and the bottom width Lb is 20 nm or greater.

Also in this embodiment, the same effect as in the third embodiment can be obtained.

### Fifth Embodiment

FIG. 13 is a sectional view schematically illustrating a configuration of a photoelectric converting element 5 according to the fifth embodiment of the invention. The photoelectric converting element 5 includes a silicon substrate 501, a passivation film 502, the transparent conductive film 105, and the electrodes 106 and 307.

In the silicon substrate 501, the conductivity type is the n type, and a p-type diffusion area 501p is formed on the light receiving surface side, and an n-type diffusion area 501n is formed on the back surface side. The electrodes 106 are formed so as to come into contact with the p-type diffusion area 501p. Also in the photoelectric converting element 5, the textured structure TX is formed on the light receiving surface side of the silicon substrate 501, and the bottom width Lb is 20 nm or greater.

The passivation film 502 may be, for example, an i-type amorphous silicon film grown by plasma CVD, or may be an oxide film formed by thermally treating the surface of the silicon substrate 501. In a portion of the passivation film 502, a contact hole for causing the p-type diffusion area 501p and the electrodes 106 to come into contact with each other is formed.

### [Method of Manufacturing the Photoelectric Converting Element 5]

Hereinafter, an example of the method of manufacturing the photoelectric converting element 5 is described. However, the method of manufacturing the photoelectric converting element 5 is not limited to the method described herein.

First, a silicon substrate having the textured structure TX formed on one surface is manufactured in the same manner as that in the third embodiment. The p-type diffusion area 501p and the n-type diffusion area 501n are formed on the silicon substrate having the textured structure TX formed on one surface.

The p-type diffusion area 501p can be formed, for example, by accumulating a B-doped siligate glass (BSG) film on the light receiving surface of the silicon substrate 501 by atmospheric chemical vapour deposition (APCVD), and thermally treating the accumulated BSG film. The concentration of the dopant of the p-type diffusion area 501p is, for example, in the range of 1×10¹⁷ cm⁻³ to 1×10¹⁸ cm⁻³.

The n-type diffusion area 501n can be formed, for example, by thermally treating the back surface of the silicon substrate 501 in the atmosphere of mixed gas of PoCl₃, N₂, and O₂. The concentration of the dopant of the n-type diffusion area 501n is, for example, 1×10¹⁷ cm⁻³ to 1×10¹⁸ cm⁻³.

Subsequently, the passivation film 502 is formed. As described above, the passivation film 502 may be an i-type amorphous silicon film grown by plasma CVD, or may be an oxide film formed by thermally treating the surface of the silicon substrate 501. A contact hole for causing the p-type diffusion area 501p and the electrodes 106 to come into contact with each other is formed by photolithography.

Subsequently, the transparent conductive film 105 and the electrodes 106 and 307 are formed. The transparent conductive film 1105 can be formed, for example, by sputtering. The electrodes 106 can be formed, for example, by a print method. The electrode 307 can be formed, for example, by sputtering.

### [Effect of Fifth Embodiment]

Also in this embodiment, in the concave portion TXb of the textured structure TX formed on the light receiving surface side, the stress applied to the passivation film 502 is relieved. Accordingly, the conversion efficiency can be enhanced.

According to the embodiment, the pn junction is formed by forming the p-type diffusion area 501p on the silicon substrate 501, the conductivity type of which is the n type, but when an n-type diffusion area is formed on the p-type silicon substrate, the same effect can be obtained.

### Sixth Embodiment

FIG. 14 is a sectional view schematically illustrating a configuration of a photoelectric converting element 6 according to the sixth embodiment of the invention. The photoelectric converting element 6 includes the silicon substrate 301, the semiconductor layers 102, 602, and 603, an insulating film 604, transparent conductive films 605 and 606, and electrodes 607 and 608.

The insulating film 604 is formed so as to cover the semiconductor layer 102. The insulating film 604 has a function as an antireflection film and a function as a protective film. The insulating film 604 is, for example, silicon oxide, silicon nitride, or silicon oxynitride. Considering passivation properties of the semiconductor layer 102, silicon nitride and silicon oxynitride are preferable. The thickness of the insulating film 604 is appropriately set according to the antireflection performance desired to be given, but, for example, in the range of 80 nm to 300 nm.

Semiconductor layers 602 and 603 come into contact with the back surface of the silicon substrate 301 and are disposed in the in-plane direction of the silicon substrate 301. A semiconductor layer 602 includes an i-type amorphous film 602i and an n-type amorphous film 602n. A semiconductor layer 603 includes an i-type amorphous film 603i and a p-type amorphous film 603p. The i-type amorphous films 602i and 603i can use the same materials used in the i-type amorphous films 102i and 103i. The n-type amorphous film 602n can use the same materials used in the n-type amorphous film 102n. The p-type amorphous film 603p can use the same materials used in the p-type amorphous film 103p.

A transparent conductive film 605 and an electrode 607 are formed on the semiconductor layer 602 in this sequence. A transparent conductive film 606 and an electrode 608 are formed on the semiconductor layer 603 in this sequence.

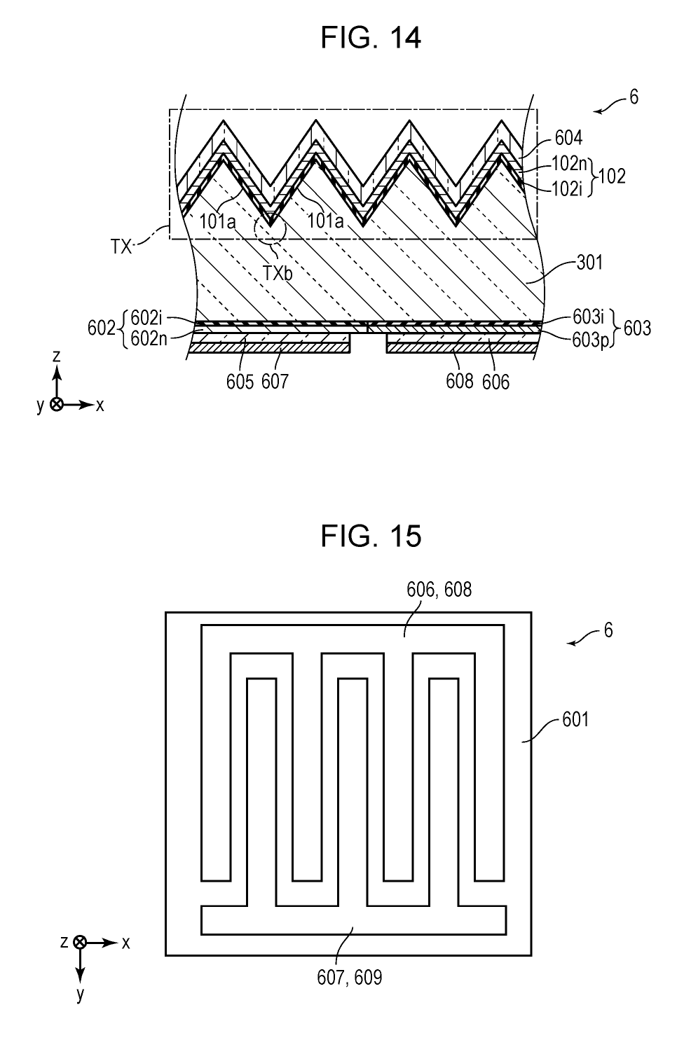

FIG. 15 is a plan view illustrating the photoelectric converting element 6 seen from the back surface side. As illustrated in FIG. 15, the transparent conductive film 605 and the electrode 607 are formed so as not to be conductive to the transparent conductive film 606 and the electrode 608.

The transparent conductive films 605 and 606 are, for example, ITO, SnO₂, or ZnO. The electrodes 607 and 608 are metal having high reflectivity such as silver. According to this configuration, the light reaching the back surface from the light receiving surface side of the photoelectric converting element 6 is reflected on the electrodes 607 and 608 having high reflectivity, and thus more light can be obtained.

Also in the photoelectric converting element 6, the textured structure TX is formed on the light receiving surface side of the silicon substrate 301, and the bottom width Lb is 20 nm or greater.

### [Method of Manufacturing the Photoelectric Converting Element 6]

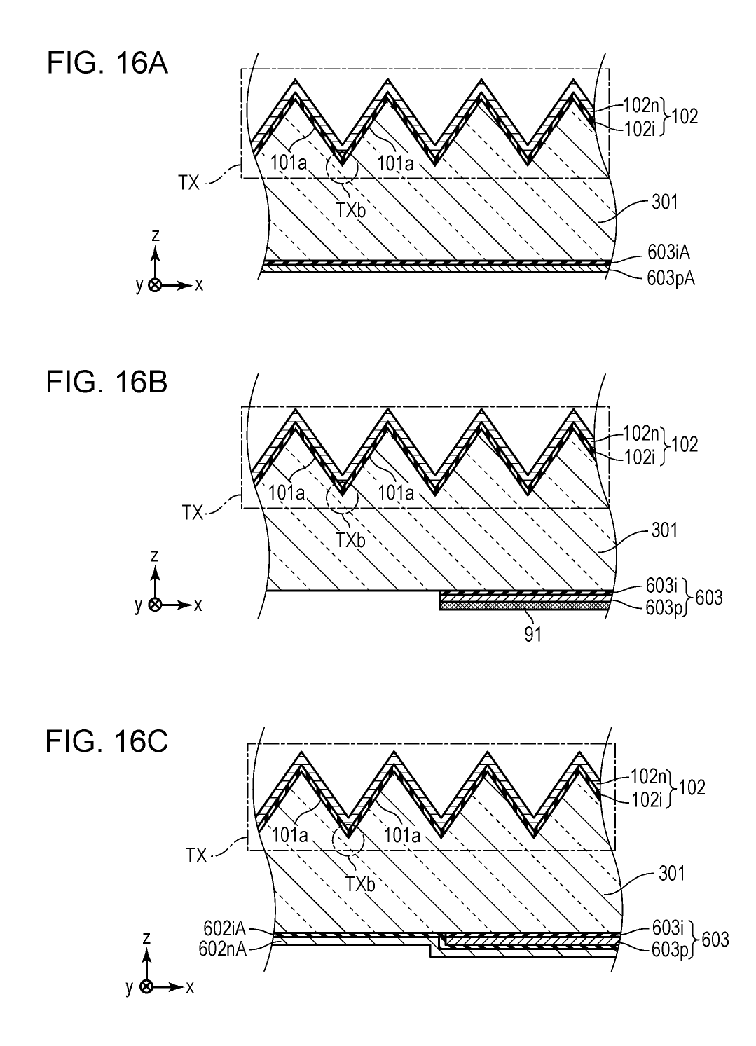

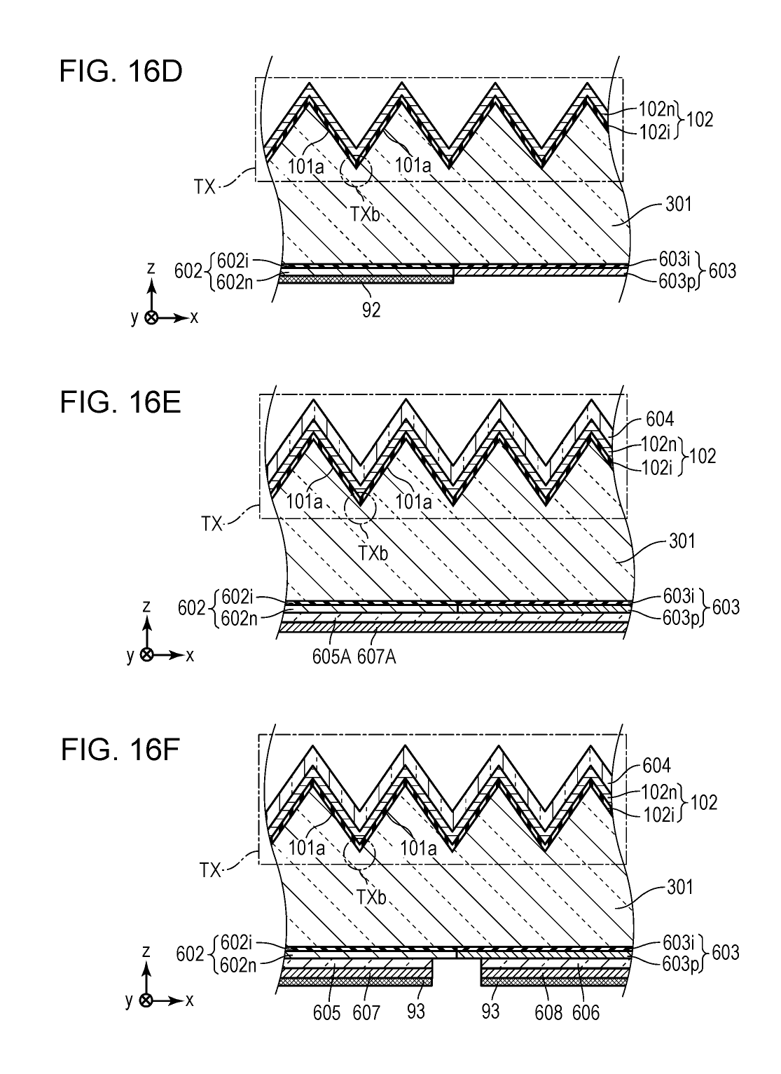

Hereinafter, with reference to FIGS. 16A to 16F, an example of a method of manufacturing the photoelectric converting element 6 is described. However, the method of manufacturing the photoelectric converting element 6 is not limited to the method described herein.

First, the silicon substrate 301 having the textured structure TX formed on one surface is produced. The silicon substrate 301 can be produced in the same manner as in the third embodiment.

Subsequently, the semiconductor layer 102 is formed on the light receiving surface side of the silicon substrate 301. The semiconductor layer 102 can be produced in the same manner as in the first embodiment.

Subsequently, the semiconductor layers 602 and 603 are formed on the back surface side of the silicon substrate 301.

First, an i-type amorphous film 603iA and a p-type amorphous film 603pA are sequentially formed so as to cover substantially the entire back surface of the silicon substrate 301 by plasma CVD (FIG. 16A). Thereafter, a resist 91 is formed by photolithography in a portion in which the semiconductor layer 603 is formed and a remaining portion is removed by etching (FIG. 16B). Accordingly, the semiconductor layer 603 is formed. After the semiconductor layer 603 is formed, the resist 91 is removed.

Subsequently, an i-type amorphous film 602iA and an n-type amorphous film 602nA are sequentially formed so as to cover substantially the entirety of the semiconductor layer 603 and the back surface of the silicon substrate 301 by plasma CVD (FIG. 16C). Thereafter, a resist 92 is formed by photolithography in a portion in which the semiconductor layer 602 is formed, and a remaining portion is removed by etching (FIG. 16D). Accordingly, the semiconductor layer 602 is formed. After the semiconductor layer 602 is formed, the resist 92 is removed.

Subsequently, the insulating film 604 is formed on the semiconductor layer 102. The insulating film 604 can be formed, for example, by APCVD.

Subsequently, a transparent conductive film 605A and a conductive film 607A are sequentially formed so as to cover the semiconductor layers 602 and 603 (FIG. 16E). The transparent conductive film 605A and the conductive film 607A can be formed, for example, by sputtering. Thereafter, resists 93 are formed by photolithography, in a portion in which the transparent conductive film 605, the electrode 607, and a portion in which the transparent conductive film 606 and the electrode 608 are formed, and a remaining portion is removed by etching (FIG. 16F). Accordingly, the transparent conductive film 605, the electrode 607, the transparent conductive film 606, and the electrode 608 are formed. After the transparent conductive film 605, the electrode 607, the transparent conductive film 606, and the electrode 608 are formed, the resists 93 are removed.

### [Effect of the Photoelectric Converting Element 6]

The photoelectric converting element 6 is a so-called back surface junction-type photoelectric converting element in which an electrode does not exist on the light receiving surface side. According to this configuration, since an electrode does not exist on the light receiving surface side, more light can be obtained.

Also in this embodiment, in the concave portion TXb of the textured structure TX formed on the light receiving surface side, the stress applied to the semiconductor layer 102 and the insulating film 604 is relieved. Accordingly, the conversion efficiency can be improved.

### Seventh Embodiment

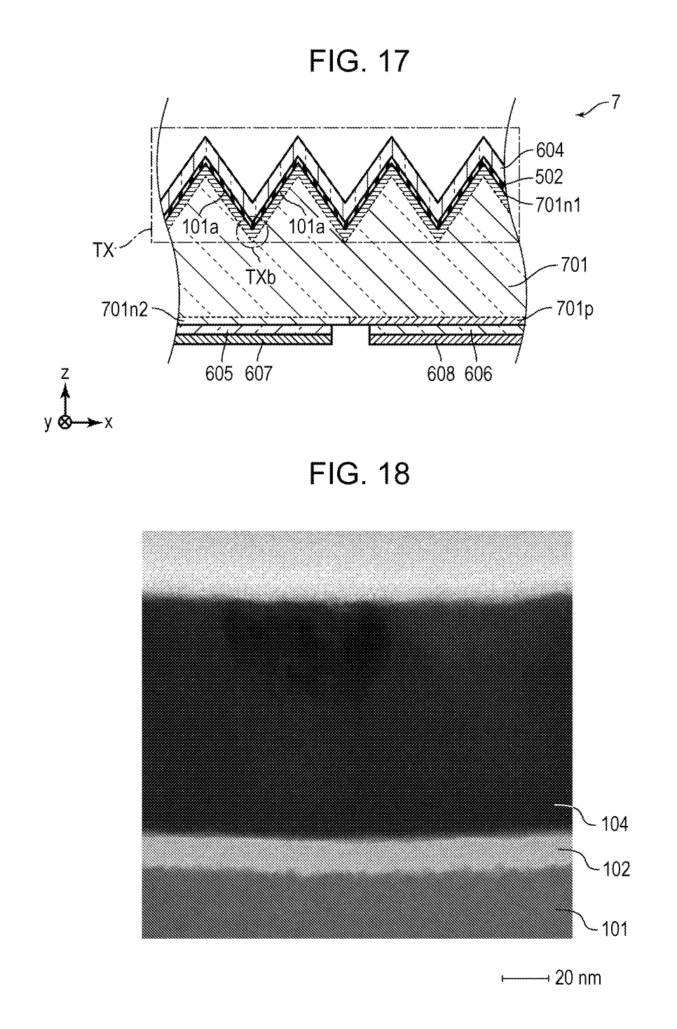

FIG. 17 is a sectional view schematically illustrating a configuration of a photoelectric converting element 7 according to the seventh embodiment of the invention. Compared with the photoelectric converting element 6, the photoelectric converting element 7 has the following difference.

The photoelectric converting element 7 includes a silicon substrate 701, instead of the silicon substrate 301. In the silicon substrate 701, the conductivity type is the n type, and an n-type diffusion area 701n1 is formed on the light receiving surface side, an n-type diffusion area 701n2 and a p-type diffusion area 701p are formed on the back surface side. The photoelectric converting element 7 includes the passivation film 502 instead of the semiconductor layer 102. The semiconductor layers 602 and 603 are not formed. The other configurations are the same as those in the photoelectric converting element 6. Also in the photoelectric converting element 7, the textured structure TX is formed on the light receiving surface side of the silicon substrate 701, and the bottom width Lb is 20 nm or greater.

The silicon substrate 701 can be obtained by forming the n-type diffusion area 701n1, the n-type diffusion area 701n2, and the p-type diffusion area 701p on the silicon substrate having the textured structure TX formed on one side.

The n-type diffusion area 701n1 can be formed, for example, by thermally treating the light receiving surface of the silicon substrate 701 in the atmosphere of the mixed gas of PoCl₃, N₂, and O₂. The concentration of the dopant of the n-type diffusion area 701n1 is, for example, 1×10¹⁷ cm⁻³ to 1×10¹⁸ cm⁻³.

The n-type diffusion area 701n2 and the p-type diffusion area 701p are formed, for example, as described below.

First, a BSG film is accumulated by APCVD on substantially the entire back surface of the silicon substrate 701. After the BSG film is accumulated, a resist is formed by photolithography in a portion in which the p-type diffusion area 701p is formed, and a remaining portion is removed. Thereafter, the p-type diffusion area 701p is formed by diffusing boron from the BSG by a thermal treatment. The concentration of the dopant of the p-type diffusion area 701p is, for example, in a range of 1×10¹⁷ cm⁻³ to 1×10¹⁸ cm⁻³.

Subsequently, a phosphorus siligate glass (PSG) film is accumulated by APCVD on substantially the entire back surface of the silicon substrate 701. After the PSG film is accumulated, a resist is formed in a portion in which the n-type diffusion area 701n2 is formed by photolithography, and a remaining portion is removed. Thereafter, the n-type diffusion area 701n2 is formed by diffusing phosphorus from the PSG by a thermal treatment. The concentration of the dopant of the n-type diffusion area 701n2 is, for example, 1×10¹⁷ cm⁻³ to 1×10¹⁸ cm⁻³.

Also in this embodiment, in the concave portion TXb of the textured structure TX formed on the light receiving surface side, the stress applied to the passivation film 502 on the light receiving surface side and the insulating film 604 is relieved. Accordingly, the conversion efficiency can be enhanced.

According to this embodiment, the n-type diffusion area 701n1 is formed on the light receiving surface side of the silicon substrate 701. The n-type diffusion area 701n1 functions as a surface barrier. Accordingly, it is preferable that the n-type diffusion area 701n1 is formed. However, the n-type diffusion area 701n1 may not be formed.

According to this embodiment, a pn junction is formed by forming the n-type diffusion area 701n2 and the p-type diffusion area 701p on the back surface of the silicon substrate 701, the conductivity type of which is the n type. However, also in a case where the p-type diffusion area and the n-type diffusion area are formed on the back surface of the p-type silicon substrate, the same effect can be obtained.

In the above, the embodiments of the invention are described, but the invention is not limited to the embodiments described above, and various modifications are possible.

The photoelectric converting element according to an embodiment of the invention is a photoelectric converting element for converting light to electricity, and includes a silicon substrate formed on at least one side of a textured structure containing plural inclined planes. In a section perpendicular to a line in which two adjacent inclined planes which have a concave portion of the textured structure interposed therebetween intersect each other, when a distance between a point at which a tangential line of one of the two inclined planes and a tangential line of the deepest portion of the concave portion intersect each other and a point at which a tangential line of the other one of the two inclined planes and a tangential line of the deepest portion of the deepest portion of the concave portion intersect each other is set to be a bottom width, the bottom width is 20 nm or greater (first configuration).

According to the configuration described above, if the bottom width is set to be 20 nm or greater, the stress applied from the two adjacent inclined plane having concave portion interposed therebetween can be relieved. Therefore, an even passivation film can be formed on the textured structure, and conversion efficiency of the photoelectric converting element can be enhanced.

According to the first configuration, the bottom width is preferably in the range of 100 nm to 600 nm (second configuration).

According to the first or second configuration, a first amorphous intrinsic semiconductor layer which has the textured structure formed at least on the light receiving surface side of the silicon substrate and which is formed so as to come into contact with one surface of the silicon substrate, a first conductive semiconductor layer which is formed on the first amorphous intrinsic semiconductor layer and which has a conductivity type different from that of the silicon substrate, a second amorphous intrinsic semiconductor layer formed so as to come into contact with the other surface of the silicon substrate, and a second conductive semiconductor layer which is formed on the second amorphous intrinsic semiconductor layer and which has a conductivity type identical to that of the silicon substrate may be further included (third configuration).

According to any one of the first to third configurations, it is preferable that a first transparent conductive film which has the textured structure formed on at least the light receiving surface side of the silicon substrate and which is formed on the light receiving surface side of the silicon substrate is further included (fourth configuration).

According to the configuration as described above, electric currents are easily extracted from the photoelectric converting element by the first transparent conductive film. If the bottom width is 20 nm or greater, the stress received by the first transparent conductive film is relieved, and thus the resistance of the first transparent conductive film is prevented from decreasing.

According to any one of the first to third configurations, a second transparent conductive film which has the textured structure formed on at least the opposite side of the light receiving surface of the silicon substrate and which is formed on the opposite side of the light receiving surface of the silicon substrate, and a metal film formed on the second transparent conductive film may be further included (fifth configuration).

According to the configuration described above, by the second transparent conductive film and the metal film, the usage rate of the light can be increased by reflecting light reaching the opposite side of the light receiving surface of the silicon substrate. If the bottom width is 20 nm or greater, the stress received by the second transparent conductive film can be relieved, and thus the resistance of the second transparent conductive film can be prevented from increasing.

According to the first and second configuration, a first amorphous intrinsic semiconductor layer which has the textured structure formed on the at least the light receiving surface side of the silicon substrate and which is formed so as to come into contact with the light receiving surface of the silicon substrate, a second amorphous intrinsic semiconductor layer and a third amorphous intrinsic semiconductor layer which are formed so as to come into contact with the other surface of the silicon substrate and which are disposed in an in-plane direction of the silicon substrate, a first conductive semiconductor layer which is formed on the second amorphous intrinsic semiconductor layer and which has a conductivity type different from the silicon substrate, and a second conductive semiconductor layer which is formed on the third amorphous intrinsic semiconductor layer and which has a conductivity type identical to that of the silicon substrate may be further included (sixth configuration).

According to any one of the first to sixth configurations, it is preferable that the length of one side of the bottom surface of the convex portion of the textured structure is in the range of 0.6 μm to 20 μm.

According to the configuration, the scattering performance of light included in the sunlight increases, and thus the light can be effectively used.

According to any one of first to seventh configurations, it is preferable that the inclination angle of the inclined plane is 48° or greater (eighth configuration).

### EXAMPLES

Hereinafter, the invention is described in detail with reference to examples. In addition, the embodiment is not intended to limit the invention.

### Example 1

A monocrystalline silicon substrate, the conductivity type of which is the n type, and a flat surface is a (100) surface was immersed in an alkaline solution, such that a silicon substrate in which textured structures were formed on both surfaces was produced. The silicon substrate in which the textured structures were formed on both surfaces was immersed in nitro hydrofluoric acid and etched.

Thereafter, in conformity with the method of manufacturing the photoelectric converting element 1 according to the first embodiment, a photoelectric converting element was produced. In addition, i-type amorphous silicon was used as the i-type amorphous films 102i and 103i, n-type amorphous silicon in which phosphorus was doped was used as the n-type amorphous film 102n, p-type amorphous silicon in which boron was doped was used as the p-type amorphous film 103p, and ITO was used as the transparent conductive films 104 and 105.

The bottom width Lb of the photoelectric converting element was 300 nm.

### Comparative Example 1

Except for performing etching with nitro hydrofluoric acid, a photoelectric converting element was produced in the same manner as in Example 1. The bottom width Lb of the photoelectric converting element was less than 20 nm.

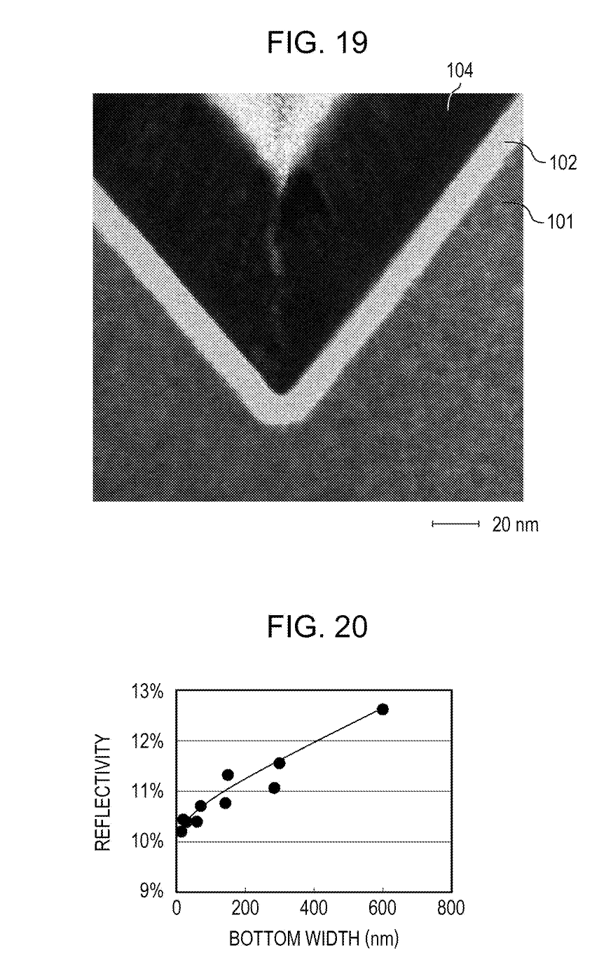

FIG. 18 is a TEM image of a section near a concave portion of a textured structure of the photoelectric converting element according to Example 1. FIG. 19 is a TEM image of a section near a concave portion of a textured structure of a photoelectric converting element according to Comparative Example 1.

As illustrated in FIG. 19, in the photoelectric converting element according to Comparative Example 1, cracks were generated on the transparent conductive film 104. As illustrated in FIG. 18, in the photoelectric converting element according to Example 1, cracks were not generated on the transparent conductive film 104.

With respect to the photoelectric converting elements according to Example 1 and Comparative Example 1, a short-circuit current density Jsc, an open circuit voltage Voc, a fill factor FF, a series resistance Rs, and a conversion efficiency η were measured. The results thereof are presented in Table 1.

TABLE 1

| | Lb | Jsc | Voc | | Rs | η |
|---|---|---|---|---|---|---|
| | nm | mA/cm² | mV | FF | R · cm² | % |
| Example 1 | 300 | 33.8 | 710.9 | 75.2 | 2.6 | 18.4 |
| Comparative Example 1 | <20 | 34.7 | 706.7 | 73.3 | 3.4 | 17.3 |

From the results above, it was found that the conversion efficiency η was greater in the photoelectric converting element according to Example 1 in which the bottom width Lb was great.

### Example 2

Subsequently, an etching treatment condition by nitro hydrofluoric acid was changed, such that plural photoelectric converting elements having different the bottom widths Lb were produced. Specifically, etching was performed by changing mixture ratios of hydrofluoric acid (50% by weight of aqueous solution) and nitric acid (60% by weight of aqueous solution) and treatment time as presented in Table 2. Except for these, the photoelectric converting elements were produced in the same manner as in Example 1. The bottom widths Lb of the photoelectric converting elements were in the range of 20 nm to 600 nm. In addition, as Comparative Example 2, without performing etching by nitro hydrofluoric acid, a photoelectric converting element was produced. The bottom width Lb of the photoelectric converting element was 15 nm.

TABLE 2

| | HF:HNO3 | Time (second) | Lb (nm) |
|---|---|---|---|
| Example 2 | 1:80 | 30 | 20 to 600 |
| | 1:80 | 60 | |
| | 1:80 | 120 | |
| | 1:40 | 30 | |
| | 1:40 | 60 | |
| | 1:40 | 120 | |
| | 1:20 | 30 | |
| | 1:20 | 60 | |
| | 1:20 | 120 | |
| Comparative Example 2 | None | None | 15 |

With respect to the photoelectric converting elements according to Example 2 and Comparative Example 2, reflectivity, the short-circuit current density Jsc, carrier lifetime, the open circuit voltage Voc, the series resistance Rs, the conversion efficiency η, and the inclination angle α were measured and the relationships thereof with the bottom width Lb were examined. The carrier lifetime was measured by using WT-2000 manufactured by Semilab Co., Ltd.

FIG. 20 is a graph illustrating a relationship between the reflectivity and the bottom width Lb of the photoelectric converting element. From FIG. 20, it is found that the reflectivity increases as the bottom width Lb increases. It is considered that this is because as the bottom width Lb increases, flat portions increase.

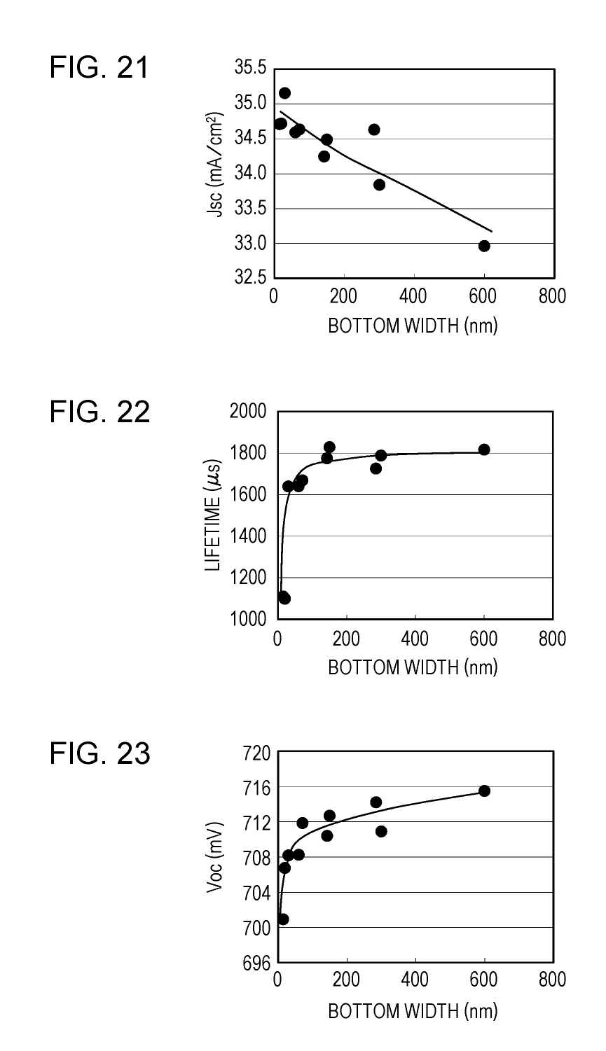

FIG. 21 is a graph illustrating a relationship between the short-circuit current density Jsc and the bottom width Lb. From FIG. 21, it is found that as the bottom width Lb increases, the short-circuit current density Jsc decreases. It is considered that this is because as the bottom width Lb increases, the reflectivity increases. If the bottom width Lb is greater than 600 nm, the short-circuit current density Jsc becomes too small, the performance of the photoelectric converting element decreases.

FIG. 22 is a graph illustrating a relationship between the carrier lifetime and the bottom width Lb. From FIG. 22, it is found that as the bottom width Lb increases, the carrier lifetime increases. It is considered that this is because as the bottom width Lb increases, the stress received by the semiconductor layers 102 and 103 is relieved, and the silicon substrate is evenly passivated.

FIG. 23 is a graph illustrating a relationship between the open circuit voltage Voc and the bottom width Lb. From FIG. 23, it is found that as the bottom width Lb increases, the open circuit voltage Voc increases. It is considered that this is also because as the bottom width Lb increases, the silicon substrate is evenly passivated.

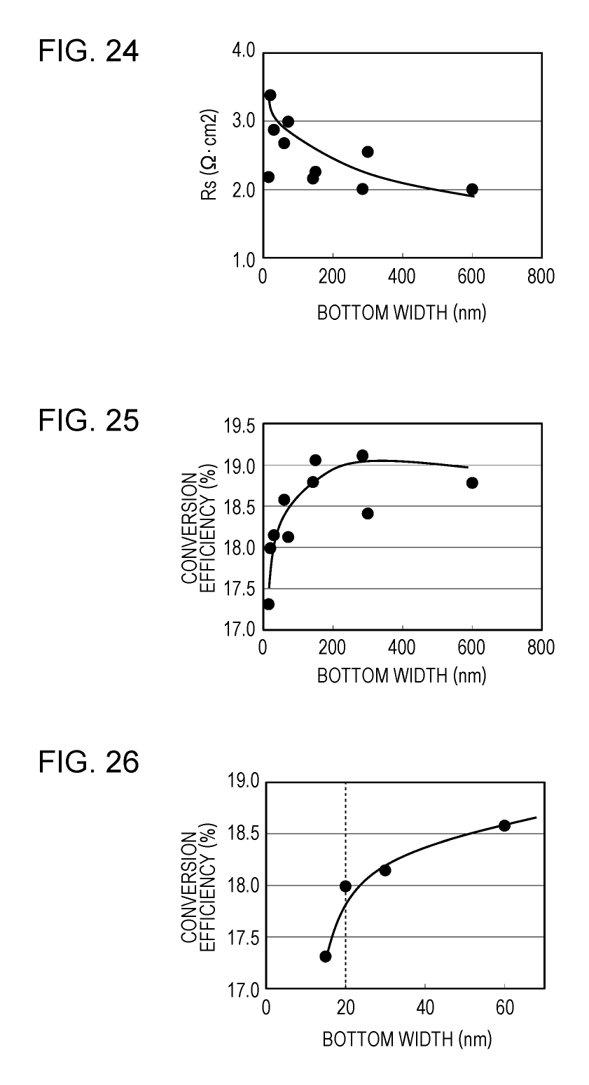

FIG. 24 is a graph illustrating a relationship between the series resistance Rs and the bottom width Lb. From FIG. 24, it is found that as the bottom width Lb increases, the series resistance Rs decreases. It is considered that this is because as the bottom width Lb increases, the stress applied to the transparent conductive film 104 and the conductive film 105 is relieved.

FIG. 25 is a graph illustrating a relationship between the conversion efficiency η and the bottom width Lb. From FIG. 25, it is found that as the bottom width Lb increases, the conversion efficiency η increases. It is considered that this is because as the bottom width Lb increases, stress received by the semiconductor layers 102 and 103 is relieved, the silicon substrate is evenly passivated, and thus the open circuit voltage Voc increases.

FIG. 26 is a diagram illustrating a portion of FIG. 25 in an enlarged manner. From FIG. 26, it is found that if the bottom width Lb is 20 nm or greater, the conversion efficiency η remarkably increases. In addition, from FIG. 25, it is found that, until the bottom width Lb becomes 100 nm, the conversion efficiency η continuously increases.

From the above, it was found that if the bottom width Lb was 20 nm or greater, the high conversion efficiency η was able to be obtained. The bottom width Lb is preferably in the range of 100 nm to 600 nm.

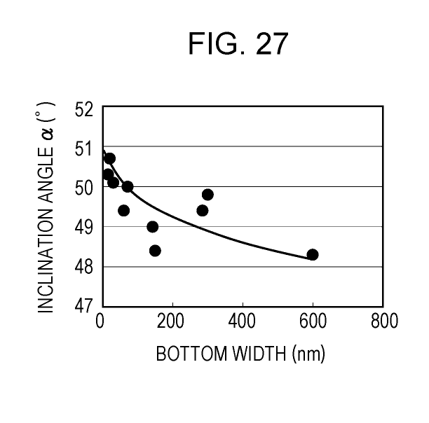

FIG. 27 is a graph illustrating a relationship between the inclination angle α and the bottom width Lb. From FIG. 27, it is found that the inclination angle α and the bottom width Lb are mutually related. In order to cause the bottom width Lb to be 600 nm or less, the inclination angle α may be 48° or greater.

Hereinafter, as another aspect of the invention, a photoelectric converting module (Eighth embodiment) including at least one of first to seventh photoelectric converting elements and a photovoltaic power generation system (ninth and tenth embodiments) are described.

The photoelectric converting elements according to the first to seventh embodiments have high conversion efficiency, and thus the photoelectric converting module and the photovoltaic power generation system including the same can also have high conversion efficiency.

### Eighth Embodiment

The eighth embodiment is a photoelectric converting module including at least one of the photoelectric converting elements according to the first to seventh embodiments.

### <Photoelectric Converting Module>

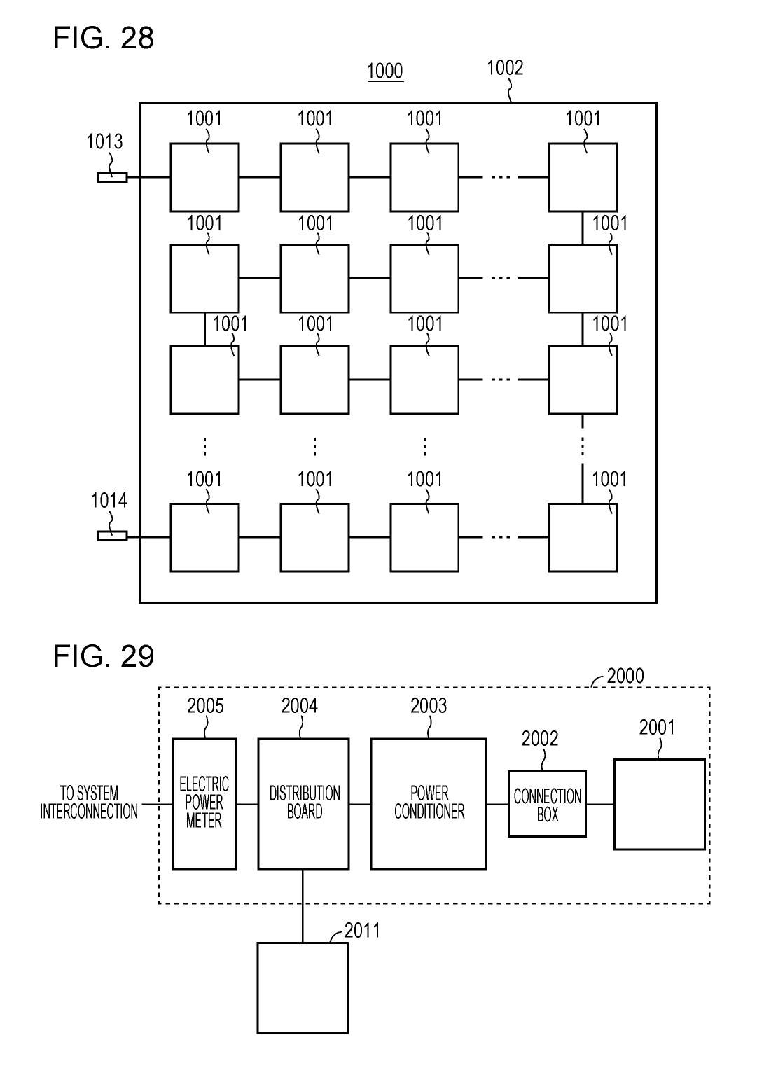

FIG. 28 is a diagram schematically illustrating an example of a configuration of a photoelectric converting module according to the embodiment. With reference to FIG. 28, a photoelectric converting module 1000 includes plural photoelectric converting elements 1001, a cover 1002, and output terminals 1013 and 1014.

The plural photoelectric converting elements 1001 are arranged in an array shape and connected to each other in series. In FIG. 28, the photoelectric converting elements 1001 are illustrated to be connected in series, but the arrangement and connection methods are not limited thereto, and the photoelectric converting elements 1001 may be connected and arranged in parallel, or may be arranged by combining series and parallel connections. Any one of the photoelectric converting elements according to the first to seventh embodiments is used in each of the plural photoelectric converting elements 1001. In addition, as long as the photoelectric converting module 1000 is not limited to the configuration described above as long as at least one of the plural photoelectric converting elements 1001 is any one of the photoelectric converting elements according to the first to seventh embodiments, and any configuration can be used. The number of the photoelectric converting elements 1001 included in the photoelectric converting module 1000 is an arbitrary integer of 2 or greater.

The cover 1002 includes a weather resistant cover, and covers the plural photoelectric converting elements 1001. The cover 1002 includes, for example, a transparent base material (for example, glass) provided on the light receiving surface side of the photoelectric converting elements 1001, a back surface base material (for example, glass and resin sheet) provided on the back surface side opposite to the light receiving surface side of the photoelectric converting elements 1001, and a sealing material (for example, EVA) burying a gap between the transparent base material and the resin base material.

An output terminal 1013 is connected to the photoelectric converting elements 1001 disposed on one end of the plural photoelectric converting elements 1001 connected in series.

An output terminal 1014 is connected to the photoelectric converting elements 1001 disposed on the other end of the plural photoelectric converting elements 1001 connected in series.

### Ninth Embodiment

The ninth embodiment is a photovoltaic power generation system including at least one of the photoelectric converting elements according to the first to seventh embodiments. The photoelectric converting element according to the invention has high conversion efficiency, and thus the photovoltaic power generation system according to the invention including the same can also have high conversion efficiency. In addition, the photovoltaic power generation system is a device that appropriately converts electric power output by the photoelectric converting module and supplies the power to a commercial power system, electrical machinery, or the like.

### <Photovoltaic Power Generation System>

FIG. 29 is a diagram schematically illustrating an example of a configuration of a photovoltaic power generation system according to the embodiment. With reference to FIG. 29, a photovoltaic power generation system 2000 includes a photoelectric converting module array 2001, a connection box 2002, a power conditioner 2003, a distribution board 2004, and an electric power meter 2005. As described below, the photoelectric converting module array 2001 includes the plural photoelectric converting modules 1000 (Eighth embodiment). The photoelectric converting element according to the invention has high conversion efficiency, and thus the photovoltaic power generation system according to the invention including the same can also have high conversion efficiency.

In the photovoltaic power generation system 2000, functions generally called a “home energy management system (HEMS)”, a “building energy management system (BEMS)”, or the like can be added. According to this, energy consumption can be reduced by monitoring the electric power generation of the photovoltaic power generation system 2000 or monitoring or controlling power consumption of respective items of electrical machinery connected to the photovoltaic power generation system 2000.

The connection box 2002 is connected to the photoelectric converting module array 2001. The power conditioner 2003 is connected to the connection box 2002. The distribution board 2004 is the power conditioner 2003 and electrical machinery 2011. The electric power meter 2005 is connected to the distribution board 2004 and commercial power system.

In addition, a storage battery 2100 may be connected to the power conditioner 2003 as illustrated in FIG. 32. In this case, the output variation due to the variation of a volume of sunshine duration can be suppressed, and the electric power stored in the storage battery 2100 can be supplied even at time when there is no sunlight. The storage battery 2100 may be embedded in the power conditioner 2003.

### (Operation)

Operations of the photovoltaic power generation system 2000 are described.

The photoelectric converting module array 2001 converts the sunlight into the electric power, generates direct current power, and supplies the direct current power to the connection box 2002.

The power conditioner 2003 converts the direct current power received from the connection box 2002 to alternate current power, and supplies the power to the distribution board 2004. In addition, the power conditioner 2003 may supply the direct current power to the distribution board 2004, as it is, without converting a portion or all of the direct current power received from the connection box 2002 to the alternating current power.

In addition, as illustrated in FIG. 32, if the storage battery 2100 is connected to the power conditioner 2003 (or, the storage battery 2100 is embedded in the power conditioner 2003), the power conditioner 2003 may appropriately convert a portion or all of the direct current power received from the connection box 2002 and store the power in the storage battery 2100. The electric power stored in the storage battery 2100 is appropriately supplied to the power conditioner 2003 side according to the conditions of the electric power generation of the photoelectric converting module and the electric power consumption of the electrical machinery 2011, are appropriately converted, and are supplied to the distribution board 2004.

The distribution board 2004 supplies at least any one of the electric power received from the power conditioner 2003 and the commercial power received via the electric power meter 2005 to the electrical machinery 2011. In addition, when the alternating current power received from the power conditioner 2003 is greater than the electricity consumption of the electrical machinery 2011, the distribution board 2004 supplies the alternating current power received from the power conditioner 2003 to the electrical machinery 2011. In addition, remaining alternating current power is supplied to the commercial power system via the electric power meter 2005.

In addition, when the alternating current power received from the power conditioner 2003 is less than the electricity consumption of the electrical machinery 2011, the distribution board 2004 supplies the alternating current power received from the commercial power system and the alternating current power received from the power conditioner 2003 to the electrical machinery 2011.

The electric power meter 2005 measures the power in the direction from the commercial power system to the distribution board 2004, and measures the electric power in the direction from the distribution board 2004 to the commercial power system.

### (Photoelectric Converting Module Array)

The photoelectric converting module array 2001 is described.

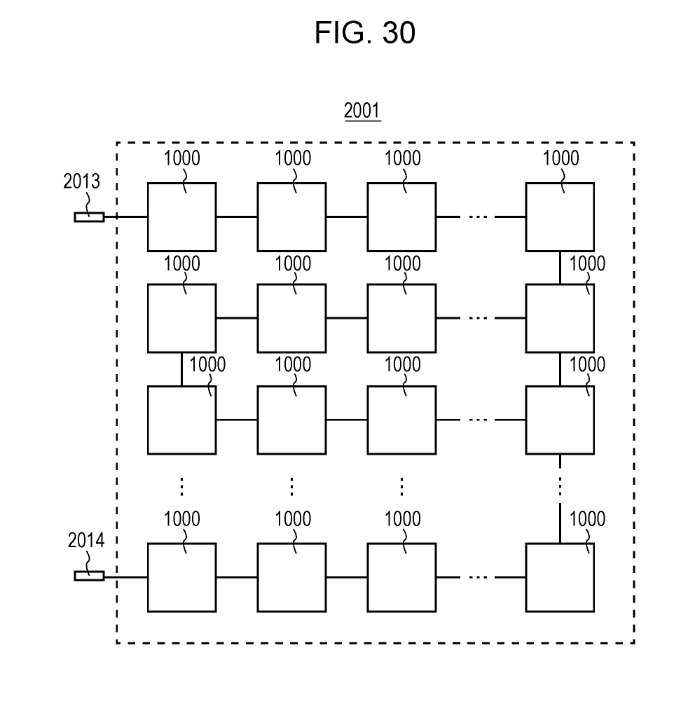

FIG. 30 is a diagram schematically illustrating an example of a configuration of the photoelectric converting module array 2001 illustrated in FIG. 29. With reference to FIG. 30, the photoelectric converting module array 2001 includes the plural photoelectric converting modules 1000 and output terminals 2013 and 2014.

The plural photoelectric converting modules 1000 are arranged in an array shape, and are connected to each other in series. In FIG. 30, an arrangement in which the photoelectric converting modules 1000 are connected to each other in series, but the arrangement and connection methods are not limited thereto, and the photoelectric converting modules 1000 may be connected and arranged in parallel, or may be arranged by combining series and parallel connections. In addition, the number of the photoelectric converting modules 1000 included in the photoelectric converting module array 2001 may be an arbitrary integer of two or greater.

An output terminal 2013 is connected to the photoelectric converting module 1000 positioned on one end of the plural photoelectric converting modules 1000 connected to each other in series.

An output terminal 2014 is connected to the photoelectric converting module 1000 positioned on one other end of the plural photoelectric converting modules 1000 connected to each other in series.

The descriptions above are provided as examples, and the photovoltaic power generation system according to the embodiment is not limited to the above description as long as at least one of the plural photoelectric converting elements 1001 is any one of the photoelectric converting elements according to the first to seventh embodiments, and any configuration can be used.

### Tenth Embodiment

The tenth embodiment is a photovoltaic power generation system having a larger scale than that of the photovoltaic power generation system described as the ninth embodiment. The photovoltaic power generation system according to the tenth embodiment also includes at least one of the photoelectric converting elements according to the first to seventh embodiments. The photoelectric converting element according to the invention has high conversion efficiency, and thus the photovoltaic power generation system including the same can also have high conversion efficiency.

### <Large Scale Photovoltaic Power Generation System>

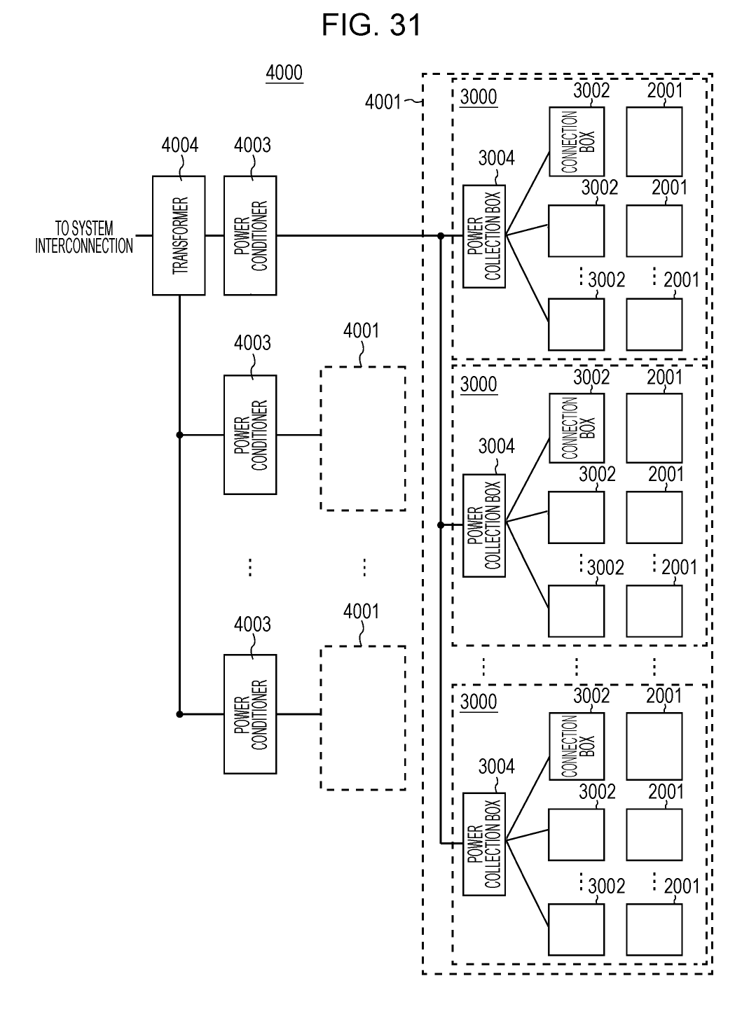

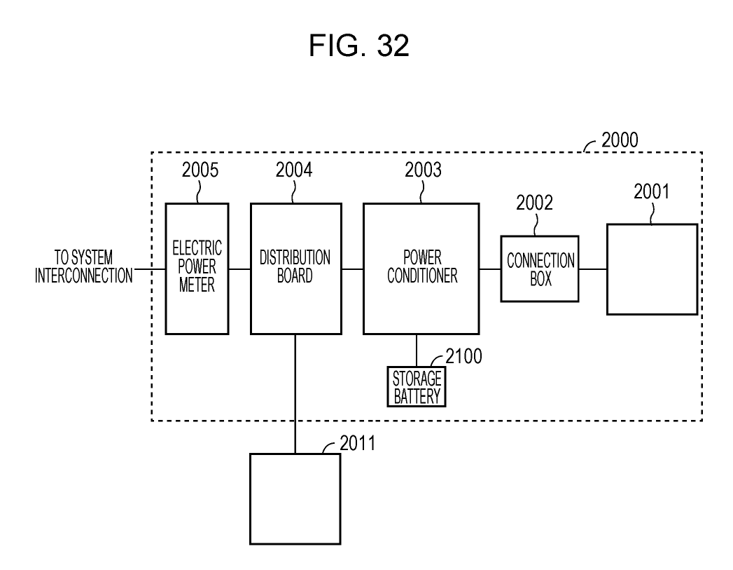

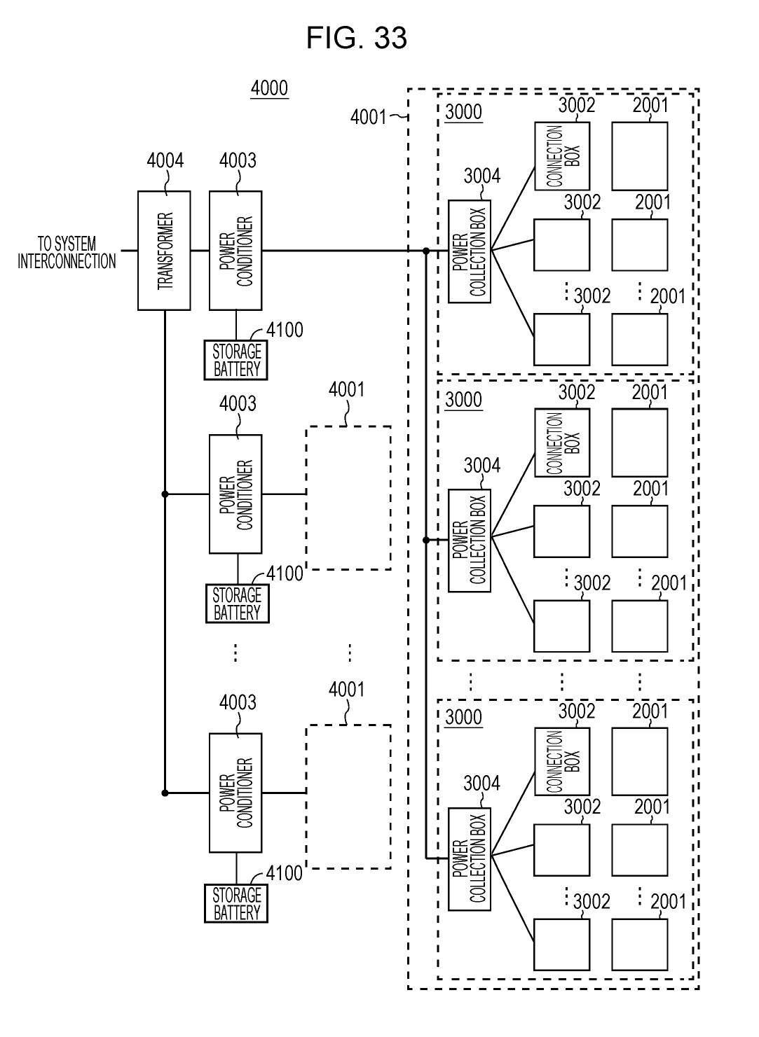

FIG. 31 is a diagram schematically illustrating another example of a configuration of a photovoltaic power generation system according to the embodiment. With reference to FIG. 31, a photovoltaic power generation system 4000 includes plural subsystems 4001, plural power conditioners 4003, and a transformer 4004. The photovoltaic power generation system 4000 is a photovoltaic power generation system having a larger scale than that of the photovoltaic power generation system 2000 illustrated in FIG. 29. The photoelectric converting element according to the invention has higher conversion efficiency, and thus the photovoltaic power generation system including the same can also have high conversion efficiency.

The plural power conditioners 4003 are connected to the subsystems 4001, respectively. In the photovoltaic power generation system 4000, the numbers of the power conditioners 4003 and the subsystems 4001 connected thereto may be an arbitrary integer of 2 or greater.

In addition, as illustrated in FIG. 32, in the power conditioners 4003, a storage battery 4100 may be connected. In this case, the power variation due to the variation of a volume of sunshine duration can be suppressed, and the electric power stored in the storage battery 4100 can be supplied even at time when there is no sunlight. The storage battery 4100 may be embedded in the power conditioner 4003.

The transformer 4004 is connected to the plural power conditioners 4003 and the commercial power system.

Each of the plural subsystems 4001 includes plural module systems 3000. The number of the module systems 3000 included in the subsystem 4001 is an arbitrary integer of 2 or greater.

Each of the plural module systems 3000 includes the plural photoelectric converting module arrays 2001, plural connection boxes 3002, and a power collection box 3004. The numbers of the connection boxes 3002 in the module system 3000 and the photoelectric converting module arrays 2001 are arbitrary integers of two or greater.

The power collection box 3004 is connected to the plural connection boxes 3002. In addition, the power conditioners 4003 are connected to the plural power collection boxes 3004 in the subsystem 4001.

### (Operation)

Operations of the photovoltaic power generation system 4000 are described.

The photoelectric converting module arrays 2001 of the module systems 3000 convert the sunlight into the electric power, generate direct current power, and supply the direct current power to the power collection boxes 3004 via the connection boxes 3002. The plural power collection boxes 3004 in the subsystems 4001 supply the direct current power to the power conditioners 4003. Further, the plural power conditioners 4003 convert the direct current power to the alternating current power, and supply the alternating current power to the transformer 4004.

In addition, as illustrated in FIG. 32, if the storage battery 4100 is connected to the power conditioners 4003 (or, the storage battery 4100 is embedded in the power conditioner 4003), the power conditioner 4003 may appropriately convert a portion or all of the direct current power received from the power collection boxes 3004 and store the power in the storage battery 4100. The electric power stored in the storage battery 4100 is appropriately supplied to the power conditioners 4003 side according to the conditions of the electric power generation of the subsystems 4001, is appropriately converted, and is supplied to the transformer 4004.

The transformer 4004 converts voltage levels of the alternating current power received from the plural power conditioners 4003 and supplies the power to commercial power system.

In addition, the photovoltaic power generation system 4000 may include at least one of the photoelectric converting elements according to the first to seventh embodiments, and not all the photoelectric converting elements included in the photovoltaic power generation system 4000 have to be the photoelectric converting element according to the first to seventh embodiments. For example, all the photoelectric converting elements included in a certain subsystem 4001 may be any one of photoelectric converting elements according to the first to seventh embodiments, and a portion or all of the photoelectric converting elements included in another subsystem 4001 may not be the photoelectric converting elements according to the first to seventh embodiments.

As described above, the embodiments according to the invention are described, but it is also expected that the configurations of the respective embodiments are appropriately combined from the beginning.

### INDUSTRIAL APPLICABILITY

The invention can be industrially used as a photoelectric converting element.

1. A photoelectric converting element that converts light to electricity, the photoelectric converting element comprising:
a silicon substrate having a textured structure including plural inclined planes which is formed on at least one surface,
wherein, in a section perpendicular to a line at which two adjacent inclined planes having a concave portion of the textured structure interposed therebetween intersect each other, when a distance between a point at which a tangential line of one of the two inclined planes and a tangential line of the deepest portion of the concave portion intersect each other and a point at which a tangential line of the other one of the two inclined planes and a tangential line of the deepest portion of the concave portion intersect each other is set to be a bottom width, the bottom width is in a range of 20 nm or greater.

2. The photoelectric converting element according to claim 1,
wherein the bottom width is in a range of 100 nm to 600 nm.

3. The photoelectric converting element according to claim 1, further comprising:
a first amorphous intrinsic semiconductor layer which has the textured structure formed on at least a light receiving surface side of the silicon substrate, and which is formed so as to come into contact with a surface on one side of the silicon substrate;
a first conductive semiconductor layer which is formed on the first amorphous intrinsic semiconductor layer and has a conductivity type different from that of the silicon substrate;
a second amorphous intrinsic semiconductor layer which is formed so as to come into contact with a surface on the other side of the silicon substrate; and
a second conductive semiconductor layer which is formed on the second amorphous intrinsic semiconductor layer, and has a conductivity type identical to that of the silicon substrate.

4. The photoelectric converting element according to claim 1, further comprising:
a first amorphous intrinsic semiconductor layer which has the textured structure on at least a light receiving surface side of the silicon substrate and which is formed so as to come into contact with the light receiving surface of the silicon substrate;
a second amorphous intrinsic semiconductor layer and a third amorphous intrinsic semiconductor layer which are formed so as to come into contact with a surface on the other side of the silicon substrate and which are disposed in an in-plane direction of the silicon substrate;
a first conductive semiconductor layer which is formed on the second amorphous intrinsic semiconductor layer and of which a conductivity type is different from that of the silicon substrate; and
a second conductive semiconductor layer which is formed on the third amorphous intrinsic semiconductor layer, and of which a conductivity type is identical to that of the silicon substrate.

5. The photoelectric converting element according to claim 1,
wherein a length of one side of a bottom surface of a convex portion of the textured structure is in a range of 0.6 μm to 20 μm.
